(19) United States
(12) Patent Application Publication
(10) Pub. No.: US 2018/0252781 A1
(43) Pub. Date: Sep. 6, 2018

(54) METHOD FOR ULTRA-DENSE DATA STORAGE VIA OPTICALLY-CONTROLLABLE PARAMAGNETIC CENTERS

(71) Applicant: Research Foundation of the City University of New York, New York, NY (US)

(72) Inventors: Carlos A. Meriles, Fort Lee, NJ (US); Siddharth Dhomkar, Rego Park, NY (US); Jacob Henshaw, New York, NY (US); Harishankar Jayakumar, Jersey City, NJ (US); Pablo R. Zangara, New York, NY (US)

(21) Appl. No.: 15/909,588

(22) Filed: Mar. 1, 2018

Related U.S. Application Data
(60) Provisional application No. 62/465,403, filed on Mar. 1, 2017.

(51) Int. Cl. G01R 33/32; G11B 20/18; G11B 7/24047; G11B 7/128; G11B 7/0045; G11B 11/08

(52) U.S. Cl. CPC G01R 33/323; G11B 20/18; G11B 11/08; G11B 7/128; G11B 7/0045; G11B 7/24047

(57) ABSTRACT

A method for optically storing and retrieving information is provided that irradiates spin-defect centers in a substrate with red or blue light to change the charge state to form a pattern. This pattern encodes information and long-term data storage. The information is retrieved by irradiating the pattern with red light that causes the pattern to undergo fluorescence.

### CROSS-REFERENCE TO RELATED APPLICATIONS

This application claims priority to and is a non-provisional of U.S. Patent Application 62/465,403 (filed Mar. 1, 2017), the entirety of which is incorporated herein by reference.

### STATEMENT OF FEDERALLY SPONSORED RESEARCH OR DEVELOPMENT

This invention was made with government support under grant numbers 1314205 and 1619896 awarded by the National Science Foundation. The government has certain rights in the invention.

### BACKGROUND OF THE INVENTION

The subject matter disclosed herein relates to digital data storage. Numerous devices exist for the storage of digital data. New memory technologies allowing more efficient, denser data packing are in great demand due to the growing gap between the rate at which digital information is being generated and the growth rate of the overall storage capacity.

Data may be stored in a variety of formats, including magnetic storage and optical storage formats. Each of these storage methods suffers from specific shortcomings including temperature sensitivity, sensitivity to magnetic fields as well as mechanical failure. Unfortunately, no such storage device has proven to be entirely satisfactory. An improved digital data storage device is therefore desirable such that a wider range of such devices would be available.

The discussion above is merely provided for general background information and is not intended to be used as an aid in determining the scope of the claimed subject matter.

### BRIEF DESCRIPTION OF THE INVENTION

A method is provided for optically storing and retrieving information is provided that irradiates spin-defect centers in a substrate with red or blue light to change the charge state to form a pattern. This pattern encodes information and long-term data storage. The information is retrieved by irradiating the pattern with red light that causes the pattern to undergo fluorescence.

In a first embodiment, a method for storing and retrieving information in a substrate is provided. The method comprising steps of: irradiating spin-defect centers in a substrate with a first wavelength of light, the step of irradiating causing a plurality of the spin-defect centers to change from a first charge state to a second charge state, wherein the plurality of spin-defect centers with the second charge state centers are selected to form a first pattern that corresponds to predetermined information to be stored; and optically detecting the first pattern of spin-defect centers with the second charge state to thereby retrieve the predetermined information.

In a second embodiment, a method for storing information in a diamond substrate is provided. The method comprising a step of: irradiating negatively charged nitrogen-vacancy (NV⁻) centers in a diamond substrate with a first wavelength of light, the first wavelength of light being selected from a red wavelength between 580 nm and 636 nm or a blue wavelength of light between 430 nm and 470 nm, the step of irradiating causing a plurality of negatively charged nitrogen-vacancy (NV⁻) centers to be altered by changing the plurality of negatively charged nitrogen-vacancy (NV⁻) centers to neutral NV⁰ centers, wherein the plurality of negatively charged nitrogen-vacancy (NV⁻) centers are selected to form a first pattern of neutral NV⁰ centers, the first pattern corresponds to predetermined information to be stored.

In a third embodiment, a method for storing information in a substrate with sub-diffraction resolution is provided. The method comprising sequential steps of: selecting a target spin-defect center from a plurality of spin-defect centers which are disposed in a substrate, wherein the target-spin-defect centers is proximate peripheral spin-defect centers, the plurality of spin-defect centers forming a first pattern; irradiating the plurality of spin-defects centers, including the target spin-defect center, with a first wavelength of light, the step of irradiating changing a charge state of the target spin-defect center without altering nuclear spin states of either the target spin-defect center or the peripheral spin-defect centers, the step of irradiating causing the first pattern to change into a second pattern that corresponds to predetermined information; and irradiating each peripheral spin-defect center, but not the target spin-defect center, with light to restore each peripheral spin-defect center's charge state based on each peripheral spin-defect center's nuclear spin state.

This brief description of the invention is intended only to provide a brief overview of subject matter disclosed herein according to one or more illustrative embodiments, and does not serve as a guide to interpreting the claims or to define or limit the scope of the invention, which is defined only by the appended claims. This brief description is provided to introduce an illustrative selection of concepts in a simplified form that are further described below in the detailed description. This brief description is not intended to identify key features or essential features of the claimed subject matter, nor is it intended to be used as an aid in determining the scope of the claimed subject matter. The claimed subject matter is not limited to implementations that solve any or all disadvantages noted in the background.

### BRIEF DESCRIPTION OF THE DRAWINGS

So that the manner in which the features of the invention can be understood, a detailed description of the invention may be had by reference to certain embodiments, some of which are illustrated in the accompanying drawings. It is to be noted, however, that the drawings illustrate only certain embodiments of this invention and are therefore not to be considered limiting of its scope, for the scope of the invention encompasses other equally effective embodiments. The drawings are not necessarily to scale, emphasis generally being placed upon illustrating the features of certain embodiments of the invention. In the drawings, like numerals are used to indicate like parts throughout the various views. Thus, for further understanding of the invention, reference can be made to the following detailed description, read in connection with the drawings in which:

FIG. 1A is a depiction of a substrate going through initialization, writing, erasing and re-writing steps;

FIG. 1B is a depiction of a substrate with data being recorded in three dimensions;

FIG. 2A depicts an energy diagram for NV⁻ and NV⁰;

FIG. 2B presents two forms of charge patterning;

FIG. 3A depicts a pattern resulting from parking a red beam at select locations;

FIG. 3B depicts a three-dimensional isosurface plot of the ionized pattern imprinted by a red laser;

FIG. 3C is a simulated beam intensity profile of a 632 nm Gaussian laser beam;

FIG. 4A depicts a ‘Red imprint’ protocol;

FIG. 4B depicts NV fluorescence in the bright and dark states (green and red traces, respectively) as a function of readout cycles;

FIG. 4C depicts a ‘Green imprint’ protocol;

FIG. 4D is the same as in FIG. 4B but for a green imprint. Note the accelerated fluorescence decay as a function of the number of readouts;

FIG. 5A shows schematics of a pulse sequence;

FIG. 5B depicts fluorescence after initializing into NV⁻ (solid circles) or NV⁰ (open circles) as a function of the number of repetition cycles N;

FIG. 6A depicts charge-conditional initialization of the ¹⁴N nuclear spin host into m_{I}=0 is attained via spin transfer from the optically polarized NV—electronic spin;

FIG. 6B shows NV—ODMR spectra after the application of the pulse sequence in FIG. 6A;

FIG. 6C shows the ¹⁴N spin in the m_{I}=0 state, negatively charged NVs undergo a cycle of ionization and recharge;

FIG. 7A shows the fluorescence from a red laser pulse R1 (632 nm, 100 μW, 100 μs) after illumination B1 at 450 nm for a variable time tᵢₒₙ;

FIG. 7B shows NV—fluorescence as a function of the ionization time tᵢₒₙ.

FIG. 7C shows the effect of (femtosecond) blue excitation on the nuclear spin polarization;

FIG. 7D is a NV—pulsed ODMR spectra for different ionization times;

FIG. 8A shows a pulse sequence after NV⁻ depletion via a blue laser pulse (B1, 450 nm, 400 μW, 30 μs), green illumination (G2, 532 nm, 1 mW) for a variable duration t_{rec};

FIG. 8B depicts NV⁻ fluorescence as a function of the recharge pulse duration t_{rec} upon application of the pulse sequence in FIG. 8A;

FIG. 8C shows following initialization of the ¹⁴N spin into m_{I}=0, NV⁻ centers undergo a cycle of one-photon ionization (B1, 450 nm, 400 μW, 30 μs) and recharge (G1, 532 nm, 1 mW);

FIG. 8D is a graph showing ¹⁴N polarization at various recharge times t_{rec}.

FIG. 9A depicts conditional initialization of the ¹⁴N nuclear spin host;

FIG. 9B demonstrates that, upon charge initialization into NV⁻ and ¹⁴N spin polarization into m_{I}=0, the negatively charged NV undergoes a cycle of ionization and recharge (top fluorescence images); comparison of the ODMR spectra before (left) and after (right) application of the cycle shows no change of the ¹⁴N spin polarization;

FIGS. 10A, 10B and 10C depict a strategy that uses the nuclear spin of the nitrogen host as an ancillary, illumination-insensitive memory to store the information otherwise lost during a sub-diffraction optical writing or reading process;

FIGS. 11A, 11B, 11C and 11D depicts a strategy similar to the strategy of FIGS. 10A-10C except in that step two has been altered;

FIG. 12A depicts an energy diagram for NV⁻ and NV⁰;

FIG. 12B is a schematic of the implanted diamond crystal featuring NVs at three different depths;

FIG. 12C depicts alternative experimental protocols comprising NV charge initialization, excitation, and readout;

FIG. 12D depicts fluorescence from 10-nm-deep NVs upon 594 nm excitation of variable duration and intensity;

FIG. 12E is the same as in FIG. 12D but for 532 nm excitation;

FIG. 12F shows ionization rates under 632 nm excitation for shallow (10 nm deep) and bulk NV—;

FIG. 12G is the same as above but for 594 nm excitation;

FIG. 12H shows ‘Recharge’ rates under green excitation for 10-nm-deep and bulk NVs;

FIG. 13A depicts NV—ionization rates at three different depths for high-density NV ensembles;

FIG. 13B depicts NV—ionization rates at three different locations of variable NV⁻ content within the 10-nm-deep implanted strip;

FIG. 13C shows that, for a given implantation depth, the absolute rates tend to decrease with NV density;

FIG. 13D shows confocal fluorescence microscopy in the low density end of the 10-nm-deep strip allows us to identify individual NV⁻ emitters;

FIG. 13E shows a fluorescence time trace where conversion between the negative and neutral charge states shows in the form of blinking;

FIG. 13F shows that averaging over a set of individual bulk or shallow NVs (totaling 10 and 12, respectively), similar ionization and recombination rates were found;

FIG. 14A shows a 594 nm readout pulse immediately after the green pulse and following a dark time interval T;

FIG. 14B contains the results for various NV densities along the 10 nm deep implantation strip;

FIG. 14C shows the excess electron of a negatively charged NV at the center of a virtual diamond lattice randomly transfers to a neighboring trap;

FIG. 14D shows the averaged results of simulations for different trap densities, which are assumed to be proportional to the local nitrogen concentration;

FIG. 14E depicts optical spectroscopy of 10-nm-deep NVs under 532 nm excitation for various laser intensities in the high-density region of the implantation strip;

FIG. 14F is the same as above but for fixed laser power (650 μW) and two different NV concentrations;

FIG. 15A shows an example protocol where 532 nm initialization is followed by partial 632 nm bleach;

FIG. 15B shows NV⁻ fluorescence slightly tends to grow after a near full bleach;

FIG. 15C depicts a pulse protocol;

FIG. 15D displays images of the area of interest after charge initialization and encoding.

FIG. 16A displays a fluorescence image of a diamond plane initialized in SiV;

FIG. 16B displays a fluorescence image of a diamond plane initialized in patterned SiV⁰;

FIG. 16C a fluorescence image of a diamond plane initialized in patterned SiV⁻ and SV⁰ states;

FIG. 17A shows a way to optically control the charge-state of individual near-surface defects that can be used for ultra-dense two-dimensional memory storage; and

FIG. 17B shows an embodiment that stacks multiple layers of nanodiamond-thin-films, sandwiched between layers of transparent organic material, that provides a robust platform for memory storage in three-dimensions.

### DETAILED DESCRIPTION OF THE INVENTION

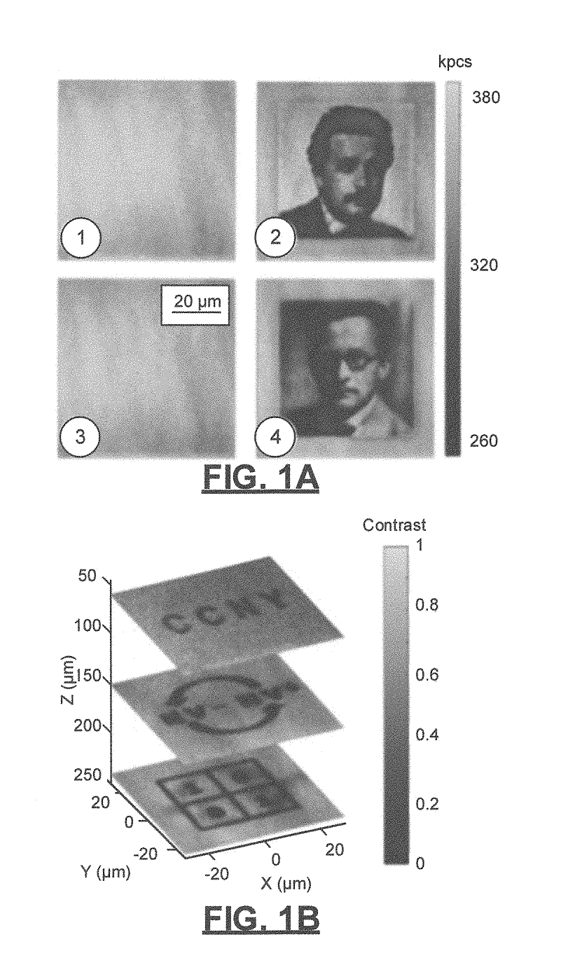

This disclosure introduces a new type of digital memory based on the manipulation of the charge state of defects in diamond. The disclosed method uses the so-called nitrogen-vacancy (NV) center, formed by a substitutional nitrogen impurity adjacent to a vacant lattice site. The charge state of an NV can be changed from neutral to negative with the use of light pulses of suitable wavelength. This change—which alters the NV fluorescence from dark to bright—is reversible, long-lasting, and robust to weak illumination, and hence serves as a platform for long-term data storage. Using alternative encoding protocols, arbitrary data sets have been written, read, erased which, without loss of generality, is present in FIG. 1A and FIG. 1B in the form of two-dimensional images. These images can be stacked on parallel planes, thus demonstrating three-dimensional data storage.

Point defects, such as the nitrogen-vacancy center, serve as local traps, where photo-generated carriers can reside for long, virtually infinite times (e.g., no change is detectable over an observation period of a week if the diamond crystal is kept in the dark). Light pulses are used to change the charge state of individual defects and, in so doing, alter the defect fluorescence properties allowing one to discriminate one state from the other. Because intense light is needed to subtract or add an excess electron to an NV, a given state can be optically readout without simultaneously altering its net charge; further, because NVs are photostable, no bleaching is induced, which allows one to write and read information countless times with no impact on the system integrity.

Additionally, one can prevent data loss during super-resolution reading or writing by resorting to the nuclear spin of the NV host (typically a ¹⁴N). The latter can be made insensitive to the NV charge state and thus serves as a temporary memory during the super-resolution ‘read’ or ‘write’ sequences provided the charge state of each NV is previously transformed into a distinct nuclear spin state. To transition from charge-encoded into spin-encoded information a pulse sequence was used that selectively polarizes the NV nuclear spin conditional on the charge state. This is possible because negative and neutral NVs have distinct magnetic resonance frequencies, which can be selectively addressed with the aid of microwave and radio-frequency pulses.

Despite the similarities with existing optical memories, the NV center simultaneously provides access to electron and nuclear spin degrees freedom, which can be exploited to reduce the volume per bit, otherwise defined by light diffraction (e.g. about 300 nm). A charge-to-spin conversion protocol is used to polarize the nuclear spin of the nitrogen host conditional on the NV charge state, and subsequently show that this polarization remains unchanged throughout a cycle of NV⁻ ionization and recharge. In combination with already proven spin-to-charge conversion schemes and super-resolution microscopy, these observations can be extended to develop a new class of three-dimensional memories with storage capacity per unit volume of order 10¹⁷ bytes per cm³ (or greater), which exceeds state-of-the-art optical memory technology by five (or more) orders of magnitude.

In FIG. 1A, frame 1 depicts a blank ensemble of NV- centers. In frame 2 information was written. In frame 2 the information was erased. In frame 4 new information was written. In frame 2 and frame 4 images were imprinted via a red laser scan with a variable exposure time per pixel. Suitable red wavelengths include 580-636 nm. Gray scale in the resulting images corresponding to multi-valued (as opposed to binary) encoding. The same scale bar applies to all four images. FIG. 1B shows information can be stored and accessed in three dimensions, as demonstrated in the figure for the case of a three-level stack.

Diamond is a unique platform material whose extreme properties and multifunctionalities are enabling an ever-growing set of applications ranging from the fabrication of long-lasting machining and cutting tools, to biomedical and low-wear coatings, and to efficient heat sinks for high-power electronics. Diamond typically contains impurities and other defects whose varying concentration and composition give gems their signature colors. An example of emerging importance is the negatively charged nitrogen vacancy (NV⁻) center, a spin 1 complex formed by a substitutional nitrogen atom adjacent to a vacant site. These paramagnetic centers can be located individually using confocal microscopy, initialized via optical pumping, and read out through spin-dependent photoluminescence measurements. Optical access coupled to a single electron spin control and millisecond-long coherence spin lifetimes under ambient conditions has led to recent demonstrations of entanglement and basic quantum logic, as well as various forms of nanoscale sensing.

Multicolor optical microscopy is used to locally convert the charge state of NVs within a dense ensemble from negative to neutral and correspondingly alter the NV fluorescence emission from bright to dark. This change is reversible, long-lasting, and robust to weak illumination, thus serving as an alternate platform for 3D information storage. To demonstrate this notion, data was written, read, erased, and rewritten, which, in one embodiment, took the form of stacked two-dimensional images. Access to the NV electron and nuclear spin degrees of freedom could be exploited to reduce the volume per bit. As a first step in this direction, a charge-to-spin (CTS) conversion protocol was used to polarize the nuclear spin of the nitrogen host, conditional on the NV charge state, and subsequently show that this polarization remains virtually unchanged throughout a cycle of NV⁻ ionization and recharge.

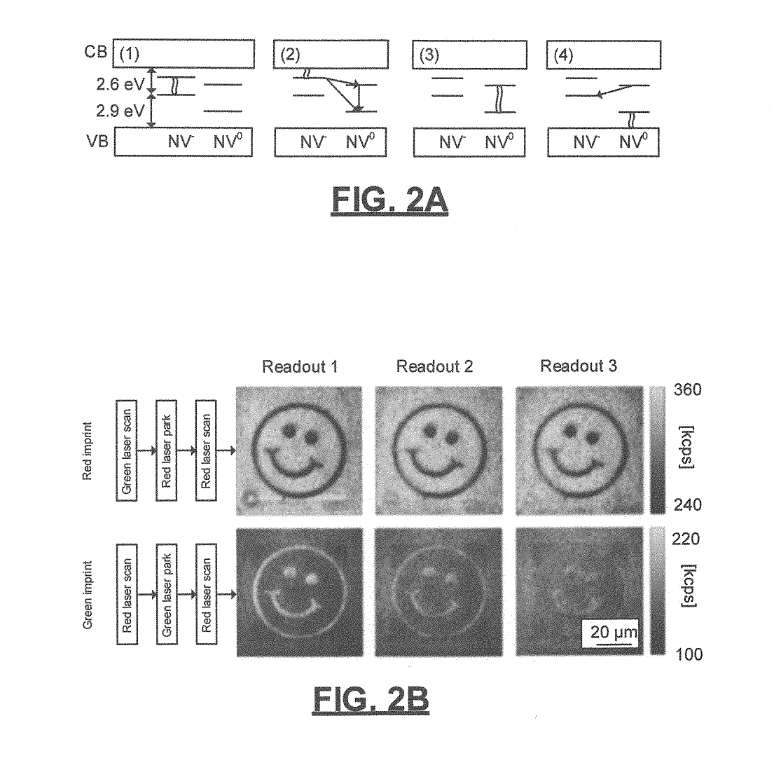

The physical mechanisms underlying NV charge dynamics are presented in FIG. 2A: green illumination (for example, at 532 nm) ionizes an NV⁻ via the consecutive absorption of two photons, thus transforming the NV⁻ into an NV⁰ (that is, a neutrally charged NV). Conversely, green light can drive a neutral NV into its excited state where absorption of an electron from the valence band reconverts NV⁰ back into NV⁻ (FIG. 2A). Suitable green wavelengths include 510-560 nm. Therefore, an NV center exposed to green light dynamically alters its charge state at a rate that depends on the illumination intensity. This behavior changes with the use of red light (for example, 632 nm), because photons of this wavelength can only excite NV⁻ but not NV⁰. Consequently, strong red illumination ionizes NV⁻ to produce NV⁰, but the back-conversion process is largely inhibited.

FIG. 2A depicts an energy diagram for NV⁻ and NV⁰. In frame (1) and frame (2), the successive absorption of two photons (wavy arrows) of energy equal or greater than 1.95 eV (637 nm) propels the excess electron of an NV⁻ into the conduction band, leaving the defect in the neutral ground state (solid arrows). In frame (3) and frame (4), an NV⁰ consecutively absorbs two photons of energy equal or greater than 2.16 eV (575 nm) transforming into NV⁻. In the figures CB refers to a conduction band while VB refers to valence bands.

A type 1b diamond crystal with an approximate NV concentration of 0.4 parts per million (ppm) was used. Two forms of charge patterning are presented in FIG. 2B. Upon initializing the focal plane into NV⁻ (upper row), select portions were converted into NV⁰ by successively parking a strong red beam at the desired pixels for a predefined time interval. Given the near quadratic dependence of the ionization rate on the illumination intensity, the resulting NV charge map can be revealed via a weak red laser scan. In this regime, charge ionization during readout is minimal, and the fluorescence—brighter in NV⁻-rich areas—correlates with NV⁻ concentration.

The lower row in FIG. 2B illustrates the converse approach where patterning is attained by parking a green beam on a “bleached” (that is, NV⁻-deprived) plane. Exposure to green light locally reconverts NV⁰ into NV⁻, and subsequent fluorescence imaging—via a weak red scan—unveils the expected bright pattern on an otherwise dark background.

In FIG. 2B A binary pattern on an NV⁻-rich background is imprinted via spatially selective red illumination (632 nm, 350 mW, 100 ms per pixel) is shown in the top row. The bottom row shows an image generated by starting from an NV⁻-depleted background, the pattern results from selective illumination with green laser light (532 nm, 30 μW, 5 ms per pixel). From left to right, images are the result of three successive readouts of the same original imprint via a red scan (200 and 150 mW for the upper and lower rows, respectively). In all cases, the image size is 100×100 pixels, and the integration time is 1 ms per pixel. Kcps is kilocounts per second.

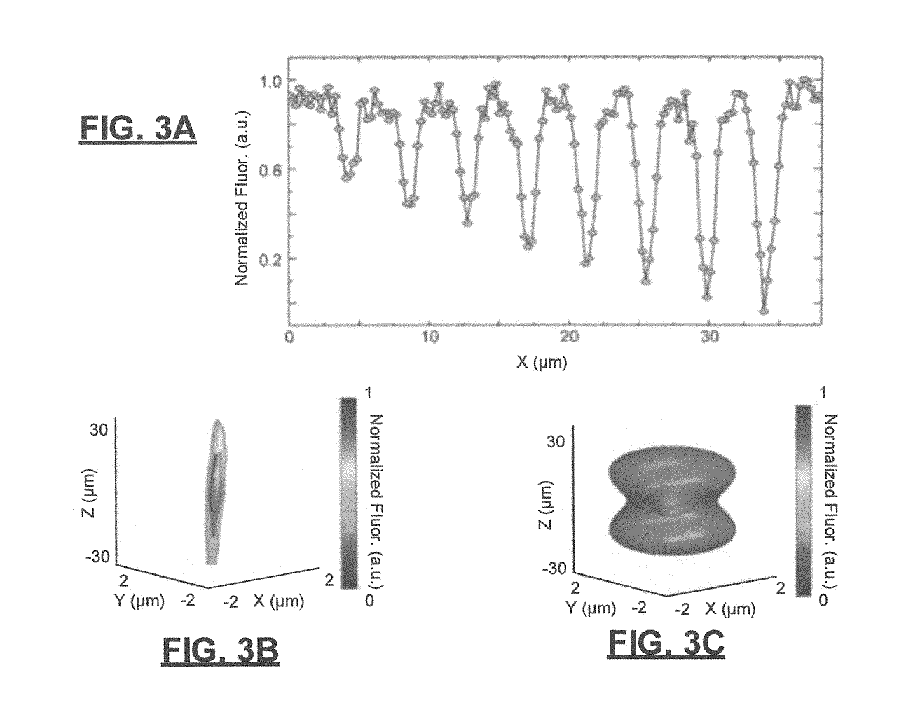

Both encoding protocols yield comparable pixel definition (about 0.8 μm; defined here by a numerical aperture of 0.42 of the objective; see FIG. 3A and FIG. 3B). However, green or red imprints respond differently to multiple red laser readouts (middle and left columns in FIG. 2B). Both exhibit a gradual loss of contrast, but the impact is substantially stronger on the green imprint. Remarkably, observations on test patterns over a period of a week show no noticeable change, provided that the diamond crystal is kept in the dark. Thus, data storage in diamond can be viewed as semi-permanent in the sense that a “refresh” protocol may be used to achieve long term storage, conditional on the number of readouts but independent on the total elapsed time.

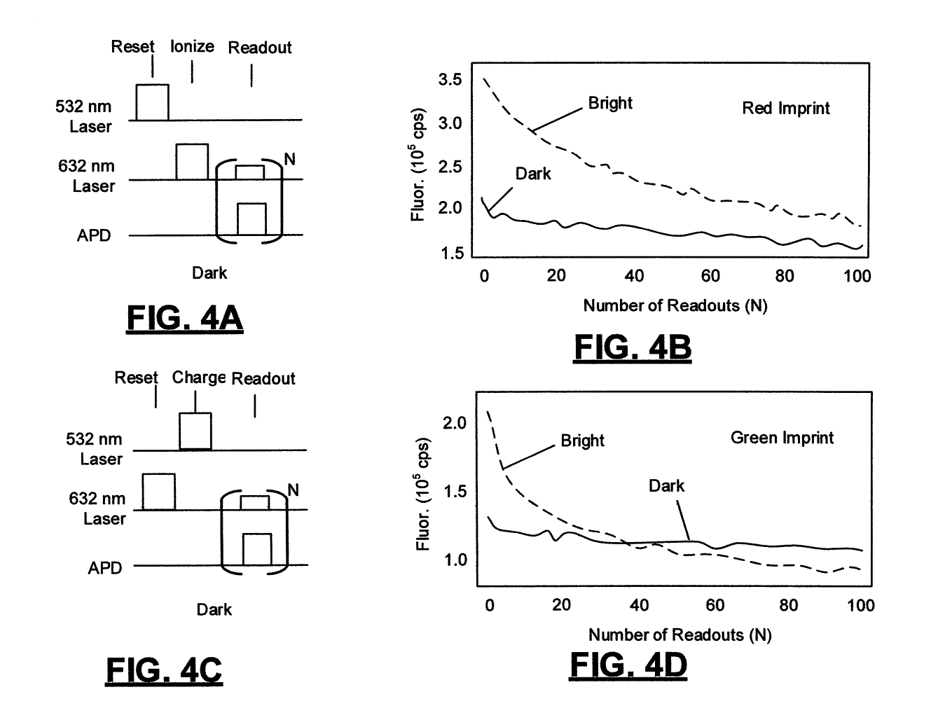

To derive a more quantitative metric, the fluorescence response from an arbitrary (but fixed) site of the diamond crystal was compared to multiple readouts (FIG. 4A; FIG. 4B; FIG. 4C and FIG. 4D relative contrast between “bright” and “dark” remains high over tens of readouts). This is not the case for a green imprint where the contrast first vanishes and then inverts.

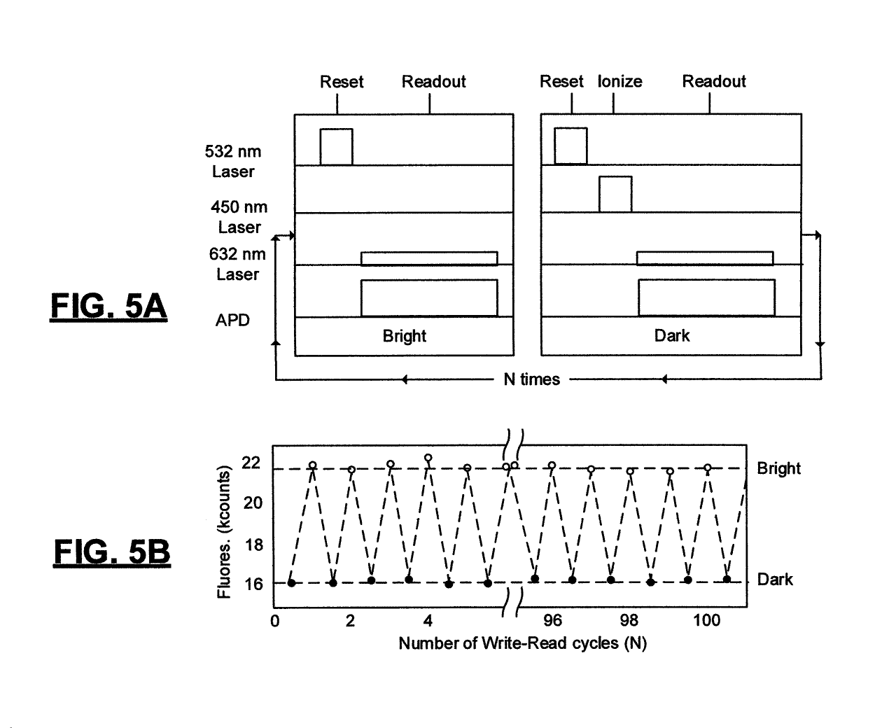

Unlike photorefractive polymers (which are prone to degradation upon repeated light exposure) or gold nanorods (which undergo a permanent photoinduced shape change), the charge state of the NV center can be reversibly altered with no accumulated effect, hence allowing one to erase and rewrite information a virtually limitless number of times. A proof-of-principle demonstration is presented in FIG. 1A (see also FIG. 5A and FIG. 5B). After resetting the NV⁻ content via a strong green laser scan (step 1), the focal plane was written through a red imprint, which was then exposed via a weak red scan (step 2); the same protocol was then repeated to encode and read out a new, different pattern (steps 3 and 4). Note that unlike FIG. 2B—where the brightness in each pixel takes one of two possible values—the images in FIG. 1A are imprinted using a variable exposure time per pixel. In the present case, the illumination times were binned into five different durations, which correspondingly lead to discernible levels of fluorescence, that is, the equivalent of a multivalued bit (FIG. 3A and FIG. 3B). The result is a concomitant boost of the information density, illustrated here via the grayscale images. The number of levels is largely defined by the signal-to-noise ratio (SNR) of the optical detection, which, in turn, grows with the square root of the readout time and NV density. In practice, considerations such as background noise and sample homogeneity must also be considered. For the examples herein, up to eight different levels seem realistic (see FIG. 3A and FIG. 3B), although more are conceivable, for example, if the sample is engineered to host a higher NV concentration.

Because the illumination intensity decays with the inverse square of the distance to the focal plane, it is possible to selectively imprint the diamond at a given depth without altering the information stored elsewhere. A demonstration is presented in FIG. 1B, where NV charge maps are written on three stacked planes approximately 90 μm apart from each other. Given the thickness of the diamond sample used (200 μm), these results indicate minimal optical aberrations throughout the crystal. On the other hand, the separation between planes—largely defined by the beam shape near the focal plane—could be reduced by resorting to beam-shaping techniques. A spatial light modulator could be used to adjust the optical wave front to reduce axial elongation in the beam profile.

Ultimately, the interplane separation results from a tradeoff between various parameters, including the required level of contrast, writing speed, and light intensity. For example, better in-plane localization is attained in the limit of low laser power, where the NV ionization rate responds quadratically to the illumination intensity, but the encoding time per pixel is comparatively longer. Faster writing speed can be reached with stronger laser power, but saturation of the first excited state gradually makes the NV ionization rate transition from quadratically to linearly dependent on the intensity, with the corresponding reduction of the in-plane localization. For a given laser power, a similar consideration applies to the light exposure time and fluorescence contrast, the latter improving with longer imprint times at the expense of a larger pixel volume (see also FIG. 3A and FIG. 3B). Note, however, that this tradeoff has a lesser impact on data density if the brighter fluorescence of larger pixels is binned into discrete levels to produce multivalued bits, as discussed above (FIG. 1A).

The absolute write and read times per pixel—either comparable to or greater than 1 ms—presently make NV storage comparatively slow. Several options exist to increase this speed. One route to faster writing makes use of stronger illumination intensities, though at the expense of higher power consumption and system complexity. For a constant average laser power, pulsed excitation may prove beneficial given the quadratic response of NV ionization upon green or red illumination. Along the same lines, different excitation colors can markedly exhibit different ionization efficiencies (for example, see conditions in FIG. 2B for red and green imprinting), thus calling for systematic characterization as a function of the excitation wavelength. In particular, the discussion below shows that NV⁻ can be efficiently ionized by blue illumination (directly exciting the excess electron into the conduction band). Suitable blue wavelengths include 430-470 nm. Although some of the same considerations also affect readout speed, the latter is mainly defined by SNR limitations, which, could be ameliorated by increasing the NV content.

Super-resolution data storage: Whereas the spatial resolution of a diamond memory—or for that matter, any other optical memory—is inherently influenced by light diffraction, a question of interest is whether the latter sets a fundamental limit to manipulate the NV charge. Super-resolution methods have already been applied to image NV centers with a spatial accuracy of up to about 6 nm, approximately 100th of the excitation wavelength. However, storing and accessing information with sub-diffraction discrimination would require that the NV charge state be preserved during the write and readout processes, a condition difficult to meet with existing super-resolution imaging methods. This incompatibility is apparent in schemes such as stochastic optical reconstruction microscopy or photoactivated localization microscopy, where spatial resolution is attained by randomly activating a small fraction of fluorophores while most of the ensemble remains in the dark state.

Sub-diffraction imaging strategies that deterministically drive NVs into a non-fluorescing state are not exempt from problems. For example, in charge state depletion (CSD) microscopy, fluorescence is recorded using weak, nonionizing illumination following the successive application of a green Gaussian beam and a concentric, doughnut-shaped red beam. The former brings most NVs within the focal area into the bright, negatively charged state, whereas the latter selectively transforms peripheral NVs into the dark, neutrally charged state. Therefore, CSD microscopy is unsuited for high-density, sub-diffraction recording because any given “write” operation initializes the charge state of NVs proximal to the target. This same drawback also applies to stimulated emission depletion (STED) microscopy and related techniques because uncontrolled NV ionization is at least as likely as stimulated emission during the application of the strong STED beam.

The ability to manipulate the NV spin degrees of freedom provides a versatile route to circumvent these problems. For example, because nuclear spins are relatively well isolated, the data loss during a super resolution read/write could be eluded via the use of a CTS conversion scheme, where the nuclear spins of all NVs within the laser focal spot are polarized, conditional on the initial NV charge state. This route exploits the NV nuclear spins as ancillary memories to temporarily store the initial charge state of all illuminated NVs during a laser read/write. Using a doughnut beam to separately address the group of NVs surrounding the target, the original charge state can be subsequently reestablished via spin-to-charge (STC) conversion. The experimental conditions are chosen so that the full protocol—including CTS, target read/write, and STC—can be assumed to take place on a time scale shorter than the spin lattice relaxation time of the NV nuclear host.

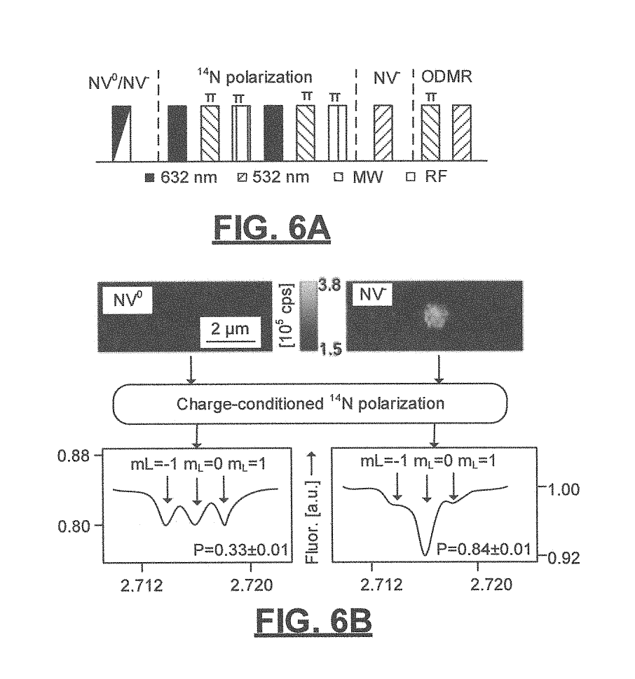

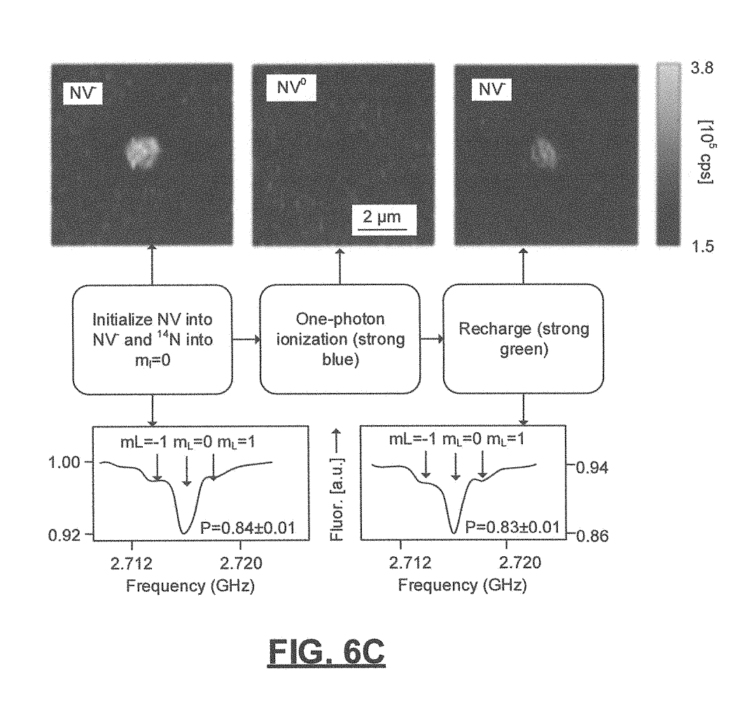

An initial proof of concept containing key ingredients necessary for the realization of the above approach is presented in FIG. 6A, FIG. 6B and FIG. 6C. Upon preparing the NVs into the negatively charged state, an optical pumping scheme was used to initialize the ¹⁴N spin of the host nitrogen atom—a system of spin number I=1—into m_{I}=0 (where m_{I} denotes the nuclear spin quantum projection along a direction coincident with the NV axis). This scheme uses a train of laser, microwave (MW), and radio frequency (RF) pulses to drive the ¹⁴N spin into the desired final state (FIG. 6A). Optically detected magnetic resonance (ODMR) of the NV—electronic spin (right column in FIG. 6B) reveals a hyperfine-split spectrum with a prominent central peak surrounded by two weak satellites, from where the level of nuclear spin polarization was estimated at about 80%.

Because both the electronic and spin energy levels depend on the center's charge state, the spin pumping protocol has no impact on the nuclear spins of neutral NVs, which consequently remain unpolarized. This charge selectivity is confirmed by interrogating NV centers initially prepared in the neutral state and subsequently converted to NV—before ODMR inspection (left column in FIG. 5B); as expected, in this case, the spectrum displays three peaks of comparable amplitude, indicative of equal ¹⁴N spin populations in all three projections. Conditional ¹⁴N spin polarization thus amounts to “charge-to-spin” conversion, with fidelity ultimately limited by the chosen nuclear spin initialization protocol.

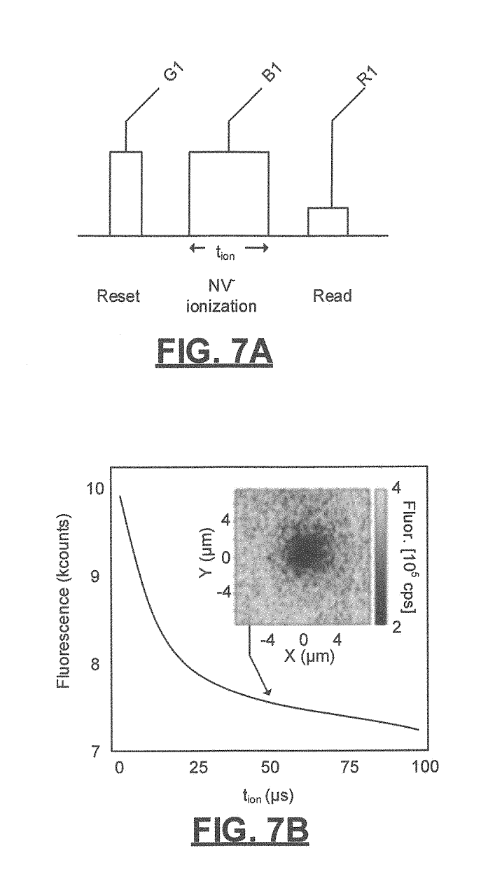

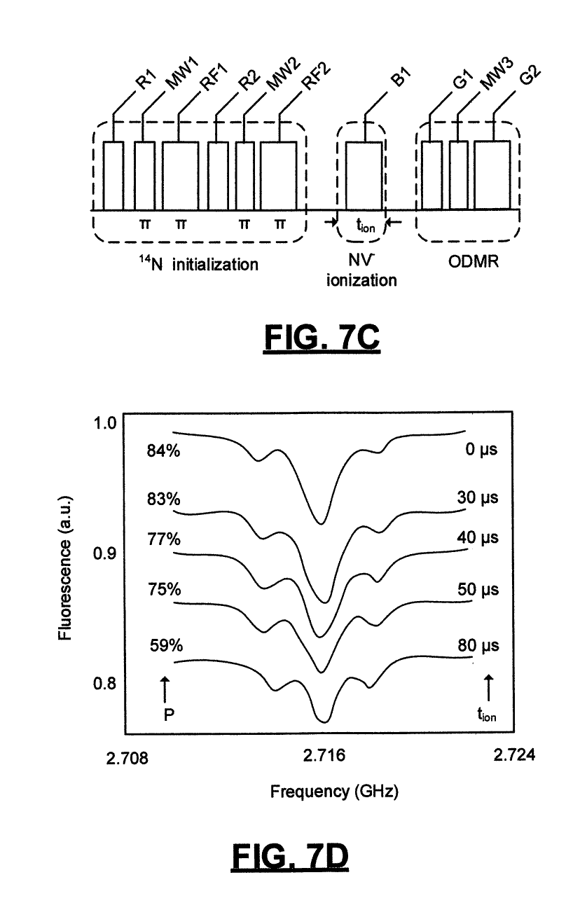

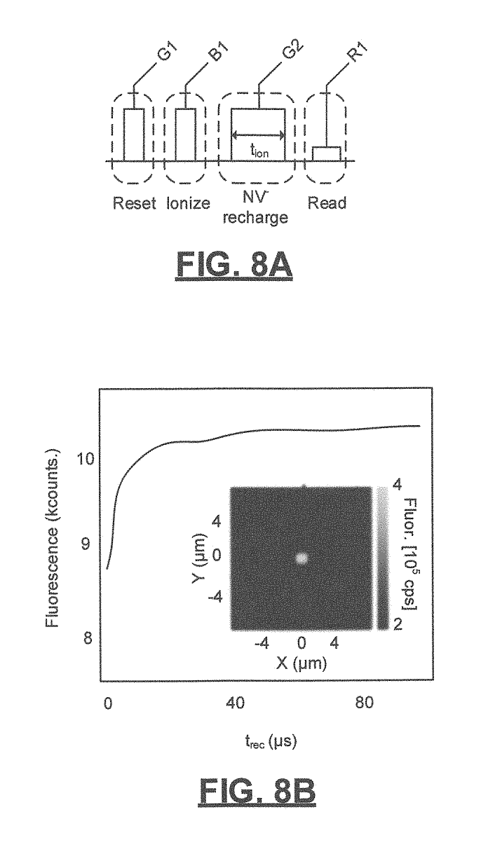

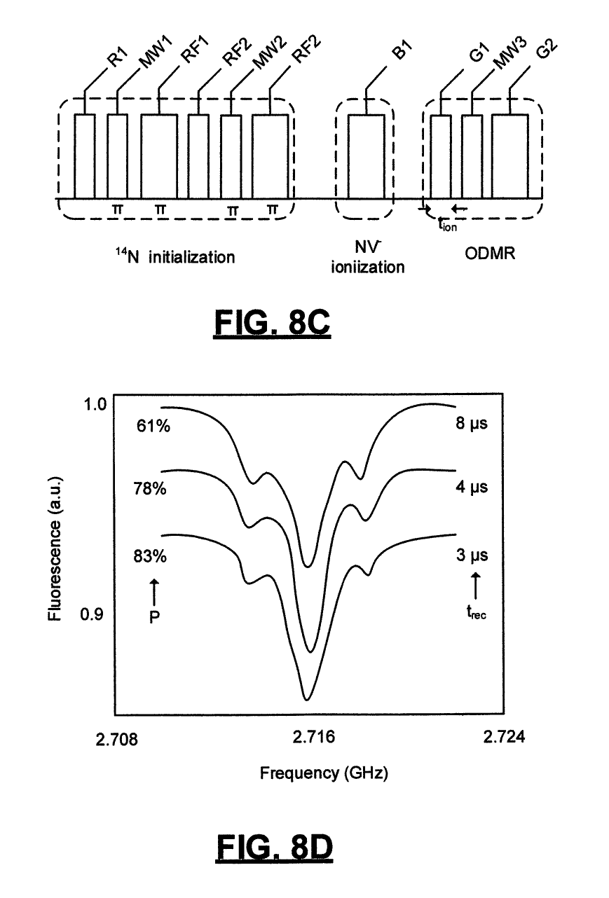

To recreate the impact of super-resolution schemes on the charge state of NVs near the target, a cycle of forced ionization and recharge (FIG. 5C) is imposed. Departing from the experiments illustrated in FIG. 2A, FIG. 2B and FIG. 1A and FIG. 1B, NV⁻ ionization is carried out this time with the aid of a femtosecond laser tuned to emit at 450 nm. Unlike red or green illumination—in which the NV undergoes a two-step process (FIG. 2A)—one-photon excitation in the blue illumination directly propels the NV⁻ excess electron into the conduction band, hence avoiding light induced nuclear spin depolarization via level mixing in the first excited state. To recharge NV⁰, a strong green laser pulse was used whose duration is optimized to yield one-directional charge conversion into the NV⁻ state with minimum ¹⁴N spin depolarization. Comparison of the ODMR spectra before and after the ionization-and-recharge cycle (lower left and right plots in FIG. 5C, respectively) virtually shows no change in the ¹⁴N spin polarization, which demonstrates data protection against photoinduced charge conversion (see also FIGS. 7A to 7D and FIGS. 8A to 8D).

Although the disclosed examples are carried out at only about 5.5 mT, greater nuclear spin resilience to photoionization is possible at higher magnetic fields (greater than 200 mT), where state mixing—driven nuclear spin relaxation in the excited state is significantly reduced. By the same token, greater nuclear spin polarization contrast between neutral and negative NVs is feasible if the CTS protocol is improved so as to polarize complementary nuclear spin projections depending on the original charge state (for example, m_{I}=−1 for NV⁻ and m_{I}=+1 for NV⁰).

Similar considerations apply to the converse operation, namely, the “spin-to-charge” transformation presently attainable at only moderate fidelities. Given the high spin selectivity of the intersystem crossing at room temperature, more efficient STC conversion is conceivable if the existing protocol is modified to induce ionization by one-photon excitation from the ground singlet state. Alternatively, it may be possible to exploit the longer electronic state lifetimes of NVs at low temperatures, though at the expense of a more complex experimental setup.

By circumventing the limitations inherent to a storage medium that is confined to two dimensions, the ideas discussed herein can be extended to include other defects also acting as electron traps. These centers could be exploited, for example, for error correction to mitigate charge instabilities from electron tunneling between neighboring NV centers or between NV centers and surrounding substitutional nitrogen atoms (most likely in crystals with high NV and nitrogen concentration). The methods described herein may be adapted for use on spin-defect centers in wide band-gap semiconductors. Examples include the silicon-carbon divacancy and the silicon vacancy in SiC as well as select rare earth ions in garnets (e.g. YAG:Ce), all of which exhibit controllable charge and electronic/nuclear spin degrees of freedom. In another embodiment, the spin-defect centers are impurities in two-dimensional semiconductors such as hexagonal boron nitride (hBN).

Materials and Methods

Diamond crystal: A type 1b diamond from Diamond Delaware Knives was used as the sample. Prior characterization via infrared spectroscopy was consistent with the presence of substitutional nitrogen atoms at a concentration of approximately 40 ppm; the estimated NV content was 0.4 ppm. The absorption near 1282 cm⁻¹ suggests that A—centers—formed by two adjacent nitrogen atoms—were, if at all present, at trace concentrations. Optical spectroscopy confirms that the collected fluorescence originated almost exclusively from NV centers. A distinctive peak at about 737 nm reveals the presence of silicon vacancy (SiV) centers; from the peak amplitude, the SiV-NV ratio is estimated to be about 0.6%.

NV magnetic resonance and optical microscopy: A custom-made, multicolor microscope was used. A 13-mW helium-neon laser and a 2 W continuous-wave solid-state laser served as the sources of red (632 nm) and green (532 nm) light, respectively. Excitation in the blue (450 nm) light was provided by a tunable ultrafast laser (Coherent Mira) and a frequency doubler generating 120-fs-long pulses at a repetition rate of 76 MHz; the average power at 450 nm was 400 mW. All laser beams were coupled into a 0.42-numerical aperture objective, which also collected the outgoing sample fluorescence. The illumination timing was set independently with the aid of acousto-optic modulators; a servo-controlled, two-mirror galvo system was used for sample scanning. Sample fluorescence ranging from 650 to 850 nm was detected after a dichroic mirror and notch filters by a solid-state avalanche photodetector.

Control of the NV⁻ electronic and nuclear spin was carried out via the use of MW and RF pulses produced by four signal generators: R&S SMB100A, R&S SMV03, Agilent E4433B, and Tektronix AFG3102. A 25-μm-diameter copper wire overlaid on the diamond surface served as the simultaneous source of the MW and RF fields. Upon amplification, the typical duration of an MW(RF) inversion pulse was 500 ns (30 μs). All magnetic resonance experiments were carried out in the presence of a 5.5-mT magnetic field emanating from a permanent magnet in the sample vicinity. The magnetic field was oriented to coincide with the sample crystal normal, that is, the axis. A pulse generator (PulseBlasterESR-PRO) controlled the timing of all laser, MW, and RF pulses. All experiments were carried out under ambient conditions.

Charge-conditioned polarization of the ¹⁴N spin: Polarization of the NV—nuclear spin is carried out using a ‘population trapping’ scheme of the form R1-MW1-RF1-R2-MW2-RF2, where R1, R2 are red (632 nm) laser pulses, and MW1, MW2 (RF1, RF2) are microwave (radio-frequency) inversion pulses (FIGS. 7A to 7D and FIGS. 8A to 8D). Briefly, red laser pulses initialize the NV⁻ electronic spin S=1 into the state |mₛ=0); since the ionization rate at this wavelength is low, the NV⁻ charge state remains unchanged so long as the pulse duration is sufficiently short. In this limit, polarization of the ¹⁴N nuclear spin I=1 into |m_{I}=0 [symbol] is the result of two successive CNOT gates each comprising two selective π-pulses: More specifically, if the NV⁻¹⁴N spin system is assumed to be in the |mₛ=0, m_{I}=1 [symbol] state, then MW1—acting selectively on the |mₛ=0, m_{I}=1 [symbol] ↔mₛ=−1, m_{I}=1 [symbol] transition—and RF1—resonant with the |mₛ=−1, m_{I}=1 [symbol] ↔mₛ=−1, m_{I}=0 [symbol] transition—produce the state |mₛ=−1, m_{I}=0 [symbol] , which then converts into |mₛ=0, m_{I}=0 [symbol] upon application of R2. On the other hand, starting from |mₛ=0, m_{I}=−1 [symbol] , MW2—selective on the |mₛ=0, m_{I}=−1 [symbol] ↔mₛ=−1, m_{I}=−1 [symbol] transition—and RF2—resonant with the |mₛ=−1, m_{I}=−1 [symbol] ↔mₛ=−1, m_{I}=0 [symbol] transition—drive the NV-¹⁴N spin state into |mₛ=−1, m_{I}=0 [symbol] , which then transforms into |mₛ=0, m_{I}=0 [symbol] upon optical pumping with red (or green) laser light. Note that throughout the protocol all pulses (including laser pulses) have no effect on neutral NVs (featuring different optical and magnetic resonance transition frequencies), hence making the ¹⁴N spin polarization conditional on the NV charge state, i.e., the equivalent of a charge-to-spin conversion.

Impact of NV⁻ ionization and recharge on the ¹⁴N spin polarization: To assess the influence of charge manipulation on nuclear spins, spin-polarized ¹⁴N spins in negatively charged NVs was subjected to a cycle of ionization and recharge via the consecutive application of blue and green laser pulses, each having a variable duration tᵢₒₙ and t_{rec}, respectively (see FIGS. 7A to 7D and FIGS. 8A to 8D). The blue laser pulse—originating from an ultrafast laser—is itself a train of 450 nm femtosecond pulses (see above). Unlike the two-photon processes presented in FIG. 2A, illumination at this wavelength ionizes NV⁻ via a one-photon absorption process. This form of ionization propels the excess electron directly into the conduction band and hence protects the ¹⁴N spin from relaxation via level mixing in the NV⁻ excited states.

During nuclear spin initialization (FIGS. 7C and FIG. 8C) microwave pulses MW1 and MW2 act selectively on the transitions |mₛ=0, m_{I}=+1 [symbol] ↔mₛ=−1, m_{I}=+1 [symbol] and |mₛ=0, m_{I}=−1 [symbol] ↔mₛ=−1, m_{I}=−1 [symbol] , respectively, whereas radio-frequency pulses RF1 and RF2 are tuned to the transitions |mₛ=−1, m_{I}=+1 [symbol] ↔mₛ=−1, m_{I}=0 [symbol] and |mₛ=−1, m_{I}=−1 [symbol] ↔mₛ=−1, m_{I}=0 [symbol] , respectively; the red (R), and green (G) laser pulse powers (durations) are 250 μW (15 μs) for pulses R1, R2, 1 mW (3 μs) for pulse G1, and 1 mW (30 μs) during pulse G2. The average blue laser power during B1 is 400 μW.

Spatial resolution of NV charge patterning. In FIG. 3A NV charges were manipulated using a dry objective with numerical aperture NA=0.42. The image in FIG. 3A shows the NV pattern resulting from parking a red beam (632 nm, 200 μW) at select locations (dark spots) separated by 4.2 μm; the exposure time increases in 10 ms steps starting from 10 ms on the left end. Readout is carried out with the same laser using a 1 ms integration time per point. A 1 mW, 532 nm laser is used initially to reset the background as explained in the main text. In FIG. 3B experimental three-dimensional isosurface plot of the ionization pattern imprinted by red laser illumination (632 nm, 200 μW, 50 ms) are shown; here the Z-axis coincides with the direction of beam propagation. FIG. 3C depicts simulated beam intensity profile for a 632 nm Gaussian laser beam focused using a 0.42 NA objective. Comparison with FIG. 3B exposes the non-linearity of the ionization process. During imaging a 632 nm laser was used for readout with a power of 200 μW and an integration time of 1 ms per pixel.

Impact of multiple readouts on NV fluorescence contrast. FIG. 4A depicts a ‘Red imprint’ protocol. After a reset laser pulse (532 nm, 1 mW, 1 ms), initialization into the ‘dark state’ (majority of NV⁰) is attained via red illumination (632 nm, 200 μW, 100 ms); alternatively, initialization into the ‘bright state’ (majority of NV⁻) omits the red pulse. FIG. 4B depicts NV fluorescence in the bright and dark states (green and red traces, respectively) as a function of readout cycles. FIG. 4C ‘Green imprint’ protocol. In this case, the bright state is produced via a red reset pulse (632 nm, 200 μW, 100 ms) followed by a green pulse (532 nm, 30 μW, 5 ms); to produce a dark initial state, the green laser pulse is skipped. FIG. 4D is the same as in FIG. 4B but for a green imprint. Note the accelerated fluorescence decay as a function of the number of readouts. In FIG. 4B and FIG. 4D the readout pulse (632 nm) has a power of 200 μW and 150 μW, respectively FIG. 4D with a duration of 1 ms.

NV response upon multiple read/write cycles. FIG. 5A shows schematics of the pulse sequence. A green laser pulse (532 nm, 1 mW, 50 μs) or a train of femtosecond pulses (each lasting 120 fs with a repetition rate of 78 MHz at 450 nm) was used to locally bring the NV ensemble into the neutral or negatively charged states, respectively. The duration and average power of the femtosecond train is 30 μs and 400 μW, respectively. To probe the resulting NV charge state the fluorescence created by red excitation (632 nm, 50 μW) was collected throughout a 200 μs time interval. FIG. 5B depicts fluorescence after initializing into NV⁻ (solid circles) or NV⁰ (open circles) as a function of the number of repetition cycles N. No change in the amplitude of the NV fluorescence contrast was observed upon multiple ionization and recharge cycles. The solid line serves as a guide to the eye.

Impact of NV⁻ ionization on the ¹⁴N nuclear spin polarization. FIG. 7A To probe the rate of NV⁻ excitation under blue excitation the fluorescence from a red laser pulse R1 (632 nm, 100 μW, 100 μs) was read out after illumination B1 at 450 nm for a variable time tᵢₒₙ. After each observation, the green laser pulse G1 (532 nm, 1 mW, 100 μs) resets the NV system to the negatively charged state. Blue excitation is generated via an ultrafast laser producing 120 fs pulses at a repetition rate of 76 MHz and with average power of 400 μW. FIG. 7B NV⁻ fluorescence as a function of the ionization time tᵢₒₙ. The insert shows an image around the point of blue illumination (coincident with the image center) after an ionization time of 50 μs. The image size is 100×100 pixels, the integration time is 1 ms per pixel and red laser power during the scan is 200 μW. FIG. 7C To assess the effect of (femtosecond) blue excitation on the nuclear spin polarization the ¹⁴N into |m_{I}=0 [symbol] was initialized and a pulsed ODMR spectroscopy was carried out preceded by illumination (450 nm, 400 μW) for a variable time tᵢₒₙ. Recharge into NV⁻ takes place during G1 (532 nm, 1 mW, 3 μs). Photon detection is carried out during the first 500 ns of G2 (532 nm, 1 mW, 30 82 s). FIG. 7D NV—pulsed ODMR spectra for different ionization times; brown squares represent data points and solid lines indicate numerical fits to a background level and three Gaussians centered around the hyperfine shifted NV⁻ spin transitions. The ¹⁴N nuclear spin polarization P is calculated as the ratio between the area under the central peak (corresponding to m_{I}=0) and the overall dip area. Comparison of the relative amplitudes in each hyperfine split spectrum shows virtually no change when tᵢₒₙ is sufficiently short.

Impact of NV⁻ recharge on the ¹⁴N nuclear spin polarization. FIG. 8A shows a pulse sequence after NV⁻ depletion via a blue laser pulse (B1, 450 nm, 400 μW, 30 μs), green illumination (G2, 532 nm, 1 mW) for a variable duration t_{rec} brings back NVs to the (mostly) negatively charged state. Readout is carried out with a red pulse (R1, 632 nm, 100 μW, 100 μs); the reset pulse (G1, 532 nm, 1 mW, 100 μs) ensures a well-defined initial state. FIG. 8B depicts NV⁻ fluorescence as a function of the recharge pulse duration t_{rec} upon application of the pulse sequence in (a). FIG. 8C shows following initialization of the ¹⁴N spin into m_{I}=0, NV⁻ centers undergo a cycle of one-photon ionization (B1, 450 nm, 400 μW, 30 μs) and recharge (G1, 532 nm, 1 mW). Photon detection is carried out during the first 500 ns of G2 (532 nm, 1 mW, 30 μs). FIG. 8D NV⁻ ODMR is used to compare the ¹⁴N polarization at various recharge times t_{rec}.

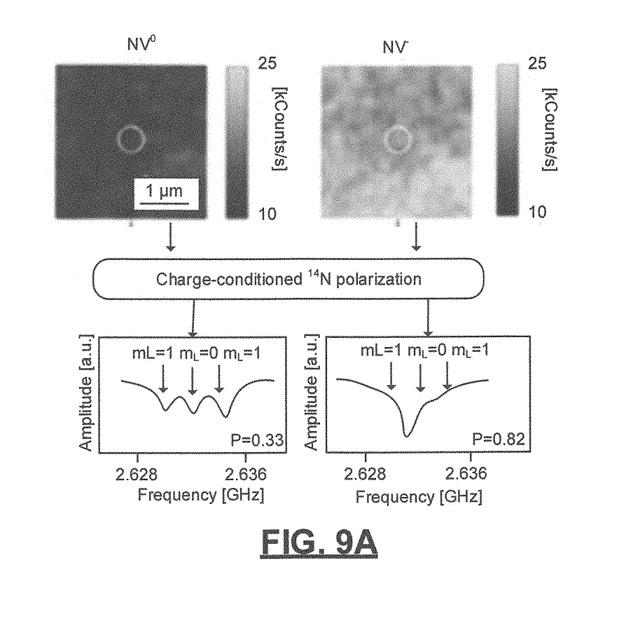

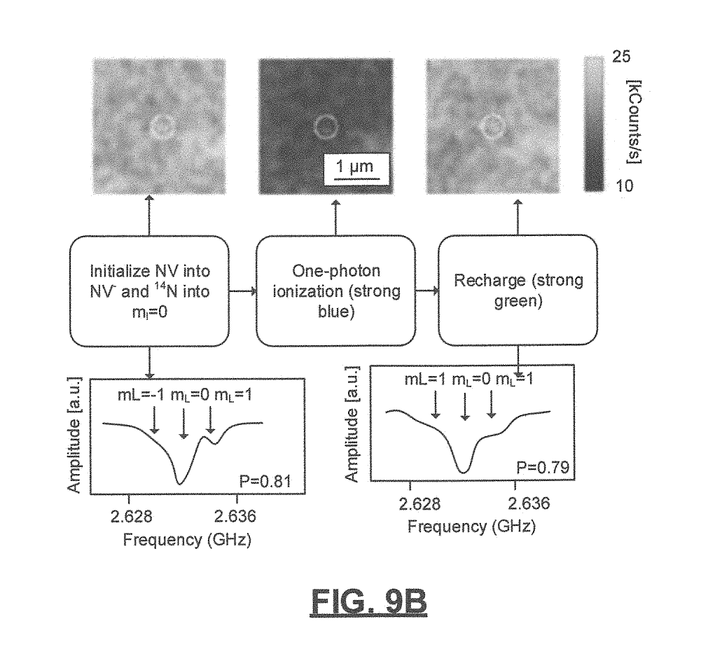

FIG. 9A depicts conditional initialization of the ¹⁴N nuclear spin host. ¹⁴N spin polarization into m_{I}=0 is attained only for the negatively charged NV. NV initialization into the neutral (left) or negative (right) charge states is created via red (632 nm, 300 μW, 5 ms per pixel) or green (532 nm, 1 mW, 1 ms per pixel) scan, respectively. ODMR spectra are obtained via a microwave sweep after unconditional initialization into NV⁻ via a 532 nm excitation (1 mW, 1 μs); the white circle indicates the area illuminated during the EPR experiments. FIG. 9B demonstrates that, upon charge initialization into NV⁻ and ¹⁴N spin polarization into m_{I}=0, the negatively charged NV undergoes a cycle of ionization and recharge (top fluorescence images); comparison of the ODMR spectra before (left) and after (right) application of the cycle shows no change of the ¹⁴N spin polarization.

FIG. 9B also presents the storage of well-defined nuclear spin polarization throughout a cycle of forced NV⁻ ionization and recharging. In the disclosed experiments the N¹⁴ spin are initialized into the state m_{I}=0 via optical pumping of the NV⁻ near the excited state level anti-crossing (which drives the nuclear spin into the state m_{I}=−1) followed by a radio-frequency (rf) inversion pulse (resonant with the ¹⁴N m_{I}=−1↔m_{I}=0 transition). Comparing the NV⁻ optically detected magnetic resonance (ODMR) spectra before and after a cycle of NV⁻ ionization and recharge the ¹⁴N spin was found to be only minimally affected (lower plots in FIG. 9B). While a full description of the physics at play is impractical, an import feature resides in the short duration and high intensity of the ionization and recharge pulses (produced by a femtosecond laser).

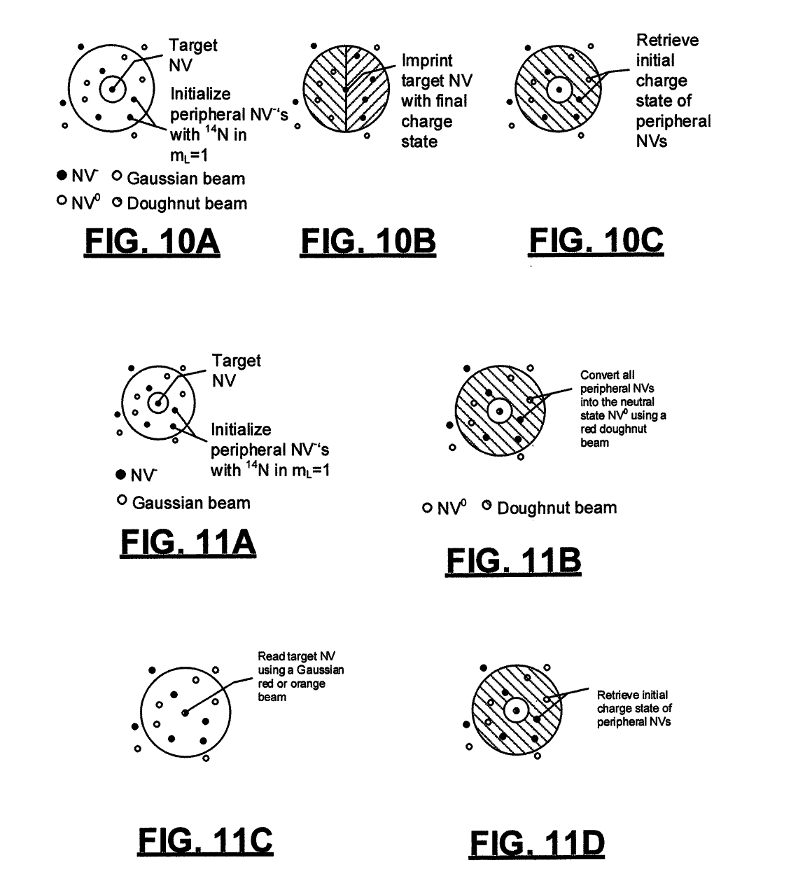

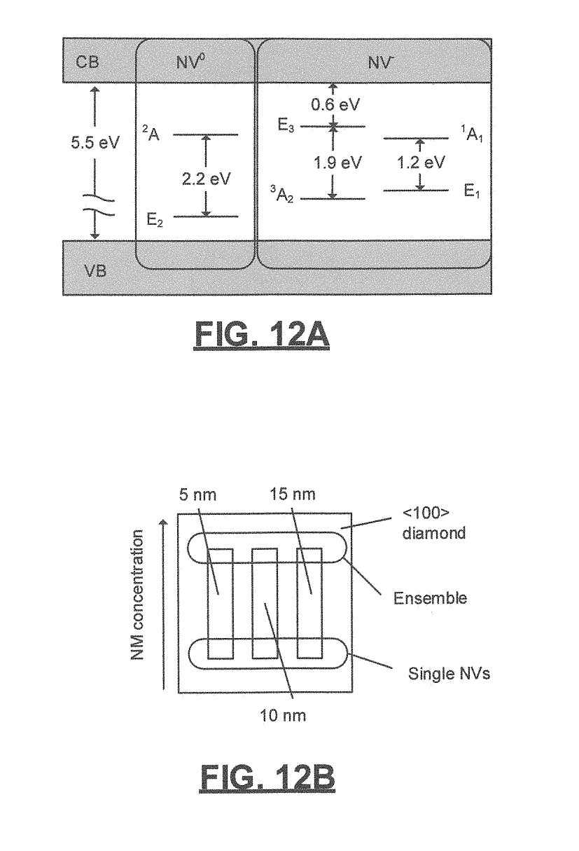

The strategy described herein uses the nuclear spin of the nitrogen host as an ancillary, illumination-insensitive memory to store the information otherwise lost during a sub-diffraction optical writing or reading process. This notion is illustrated in FIG. 10A; FIG. 10B and FIG. 10C for the case of sub-diffraction NV charge writing: The disclosed approach starts with a charge-to-spin conversion protocol in which the nuclear spin of each nitrogen host—either a spin-1 ¹⁴N or a spin-½ ¹⁵N—is polarized in a way that correlates with the original NV charge state (e.g., the N¹⁴ nuclear spin is polarized into m_{I}=1 only if the NV is negatively charged and remains unpolarized otherwise). The latter can be attained by adapting known nuclear spin polarization schemes (which act resonantly on the NV⁻ while leaving the host nitrogen of the NV⁰ unchanged). A Gaussian beam of suitable wavelength, intensity, and duration is subsequently used to imprint the target NV with its final charge state, though at the expense of affecting peripheral NVs (see FIG. 10A; FIG. 10B and FIG. 10C). The initial information is not lost so long as the write pulse does not change the nuclear spin polarization of the nitrogen host. This information can be retrieved via a spin-to-charge conversion scheme, in which peripheral NVs are selectively ionized depending on whether the nuclear spin of the nitrogen host is polarized or unpolarized. It is worth emphasizing these same ideas can be adapted to implement sub-diffraction readout, for example, by replacing step 2 in FIG. 10A; FIG. 10B and FIG. 10C by super-resolution GSD or STED protocols already used in diamond, as shown in FIG. 11A; FIG. 11B, FIG. 11C and FIG. 11D.

Shallow NV Compared to Bulk Diamond

Using multi-color confocal microscopy, the following discussion shows that superficial point defects arising from high density ion implantation dramatically increase the ionization and recombination rates of shallow NVs compared to those in bulk diamond. Further, these rates grow linearly—not quadratically—with laser intensity, indicative of single-photon processes enabled by NV state mixing with other states. NV ionization and recombination in the dark have also been observed, likely the result of charge transfer tunneling between NVs and neighboring traps. In spite of the altered charge dynamics, one can imprint rewritable, long-lasting patterns of charged-initialized, near-surface NVs over large areas, an ability that could be exploited for electrochemical biosensing or to optically store digital data sets with sub-diffraction resolution.

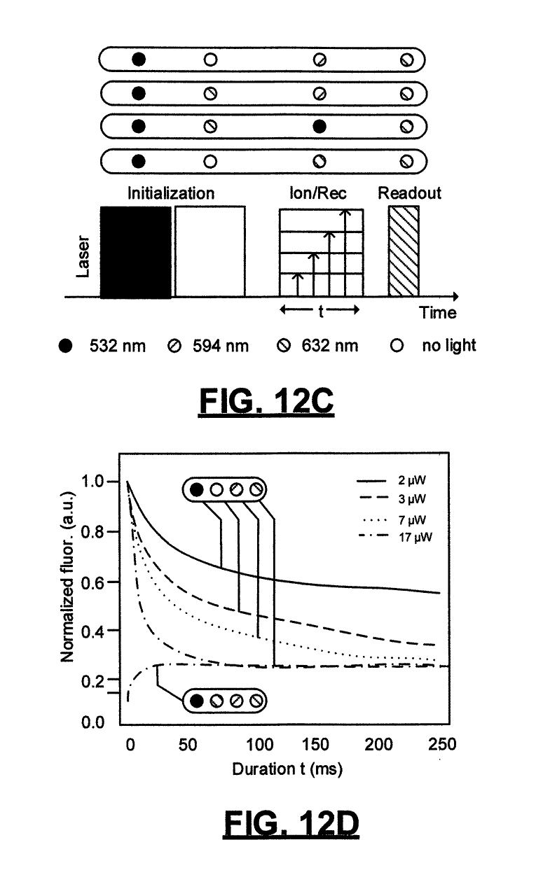

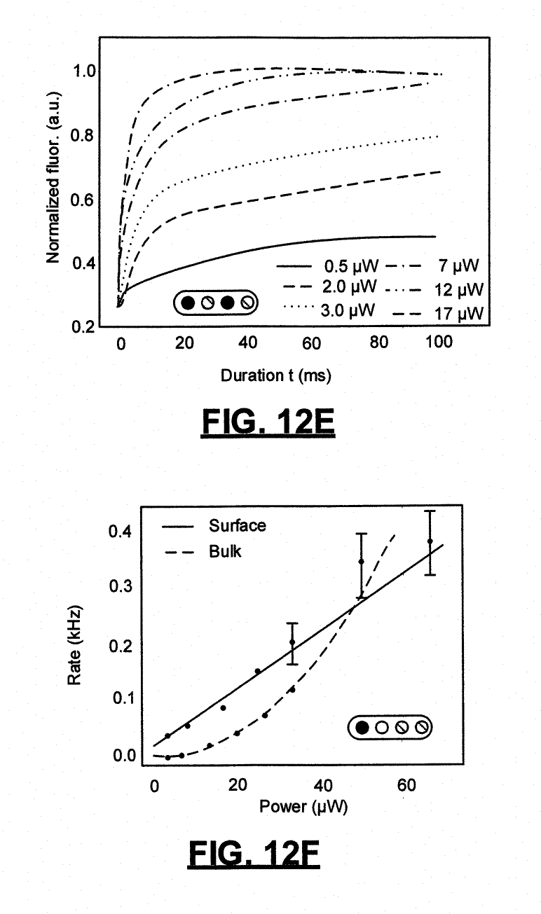

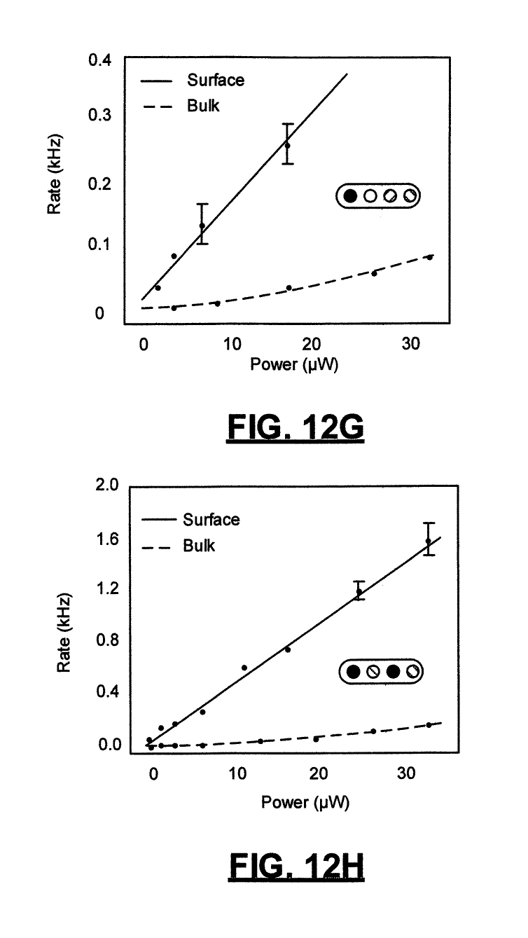

FIGS. 12A to 12H compare charge dynamics of shallow and bulk NVs. FIG. 12A is an energy level diagram of the neutral and negatively-charged NVs. CB and VB denote the conduction and valence bands, respectively. The background near the bottom of the conduction band represents an additional set of localized and delocalized states present near the surface. FIG. 12B is a schematic of the implanted diamond crystal featuring NVs at three different depths, 5, 10 and 15 nm. A concentration gradient allows us to address NV ensembles of variably size, down to individual color centers. FIG. 12C depicts alternative experimental protocols comprising NV charge initialization, excitation, and readout. The color labels above each laser pulse denotes the laser wavelength; empty circles indicate no light (and no wait time, i.e., the next light pulse follows immediately after). FIG. 12D depicts fluorescence from 10-nm-deep NVs upon 594 nm excitation of variable duration and intensity. The initial NV—population is maximum for the upper four traces and negligible for the lower trace. Solid traces indicate fits to double exponential curves; the color code denotes the laser pulse sequence as presented in (FIG. 12C). FIG. 12E is the same as in FIG. 12D but for 532 nm excitation. FIG. 12F shows ionization rates under 632 nm excitation for shallow (10 nm deep) and bulk NV—. FIG. 12G is the same as above but for 594 nm excitation. FIG. 12H shows ‘Recharge’ rates under green excitation for 10-nm-deep and bulk NVs. In FIG. 12D through FIG. 12H the power and duration of the 532 nm (632 nm) initialization pulse are 17 μW and 15 ms (17 μW and 100 or 300 ms), respectively; the duration and power of the 632 nm readout pulse are 17 μW and 500 μs, respectively.

The charge dynamics of superficial NVs were investigated via multi-color confocal microscopy. Using bulk crystal NVs as a reference, up to ten-fold faster charge conversion rates were observed, depending on the illumination wavelength. The photo-ionization and recombination rates grow linearly, not quadratically, within the range of intensities probed (less than or equal to 100 μW/μm²), indicative of distinct one-photon processes. Further, both the negative and neutral charge states are unstable and slowly interconvert in the dark to attain an equilibrium concentration that depends on the implantation conditions. Long-term charge control of surface NVs is, nonetheless, possible through the writing of arbitrary charge patterns are seen to persist over several days.

The known charge dynamics of bulk NVs exposed to optical excitation can be understood with the aid of the energy diagrams in FIG. 12A: In the negatively charged state NVs ionize into NV⁰ by ejecting an electron into the diamond conduction band via the absorption of one photon with energy greater than 2.6 eV (i.e., 477 nm) or by the successive absorption of two photons with energies greater than 1.946 eV (i.e., 637 nm). In the latter mechanism, the first photon propels NV⁻ to its first excited state and the second photon ejects the electron into the conduction band. Similarly, NV⁰ can be photo-converted back to NV⁻ either via a single photon absorption (for energies greater than 2.94 eV (422 nm)) or by another two-step process involving the absorption of a photon with energy greater than 2.156 eV (i.e., 575 nm) followed by the excitation of an electron from the diamond valence band. Relevant to the studies herein, these two-step, one-photon processes manifest experimentally in the form of a quadratic dependence on light intensity in both the ionization and recombination rates (see below). With the above constraints, red (632 nm) illumination results (mostly) in a one-directional charge conversion process, from NV⁻ into NV⁰, while the reverse process is largely suppressed. By contrast, green (532 nm) excitation dynamically modulates the NV charge state between negative and neutral; at this wavelength the equilibrium NV⁻ population is approximately 75%.

A schematic of the diamond sample is shown in FIG. 12B: Starting with an electronic grade, [100] diamond crystal (E6), focused nitrogen ion implantation was used followed by thermal annealing in vacuum to create shallow NV sets at three different average depths, namely, 5, 10, and 15 nm; during implantation the ion fluence was gradually varied to create a nitrogen concentration gradient, from an (estimated) surface density of 4.2 ppm at its maximum, down to about 0.4 ppm (vertical strips in FIG. 12B). The NV concentration was estimated from the NV formation efficiency, about 1% for the present implantation conditions. To favor the formation of negatively charged NVs, the diamond surface was partially oxygenated via acid boiling for hour long periods.

In order to determine the NV ionization and recombination rates the set of protocols described in FIG. 12C were implemented: In all cases green excitation (15 ms, 17 μW) was used to bring the initial NV⁻ population to a maximum, which was then optionally transform into mostly NV⁰ via a red laser pulse (100 or 300 ms, 17 μW), depending on the desired initial charge state. This strategy circumvents ambiguities in the starting charge distribution arising from green- and red-induced nitrogen ionization. NV charge readout is carried out with a red laser pulse (500 μs, 17 μW), whose amplitude and duration is chosen to make NV⁻ ionization negligible. This form of readout allows one to derive in each case the fractional NV⁻ population upon comparison of the observed fluorescence amplitude with that from a reference state.

Focusing for now on the charge dynamics of 10-nm deep, high-density ensembles, FIG. 12D and FIG. 12E respectively show the measured NV- fluorescence response after orange and green illumination of variable intensity and duration. In both cases a biexponential evolution was observed that featured a faster charge conversion at early times followed by a slower, asymptotic transformation towards an equilibrium charge concentration. The origin of this longer-term response—also present in bulk samples, is presently unknown but may connected to the saturation (or depletion) of available charge traps within the probed volume. To avoid ambiguities, the charge dynamics in each case were characterized through the faster response at short times, governed by the smaller time constant in the biexponential fit.

FIGS. 12F through 12H display the results corresponding to charge inter-conversion during red, orange, and green illumination, respectively. For comparison, the rates derived from similar observations in a reference Type 1b diamond are included. Depending on the initial charge state—predominantly NV⁻ or NV⁰ in FIGS. 12D and 12E, respectively—a growth or a reduction of the NV—fluorescence with pulse duration was observed. The inverse of the (shorter) time constants in either case—effectively the initial slopes in the fluorescence traces—may be referred to as the NV “ionization” and “recombination” rates, respectively. The latter is, of course, a simplification since both processes take place simultaneously, both for green and orange illumination (where significant NV⁰→NV⁻ conversion is found to take place, see lower trace in FIG. 12D).

Compared to the response within the bulk crystal, shallow NVs tend to exhibit a faster charge photodynamics at low intensities (e.g., up to ten-fold in FIG. 12G). Further, all NV charge conversion rates were found to grow linearly with laser power, very much in contrast with bulk NVs where the dependence is quadratic. These observations hint at a fundamental change in the mechanisms governing the NV charge dynamics in the form of alternate ionization/recombination channels not present in bulk crystals. The linear dependence on light intensity indicates that one-photon processes—where the NV charge state changes upon absorption of a single photon—become dominant. The latter, in turn, is likely the result of mixing between the states of the NV and other localized (or delocalized) states originating from neighboring defects.

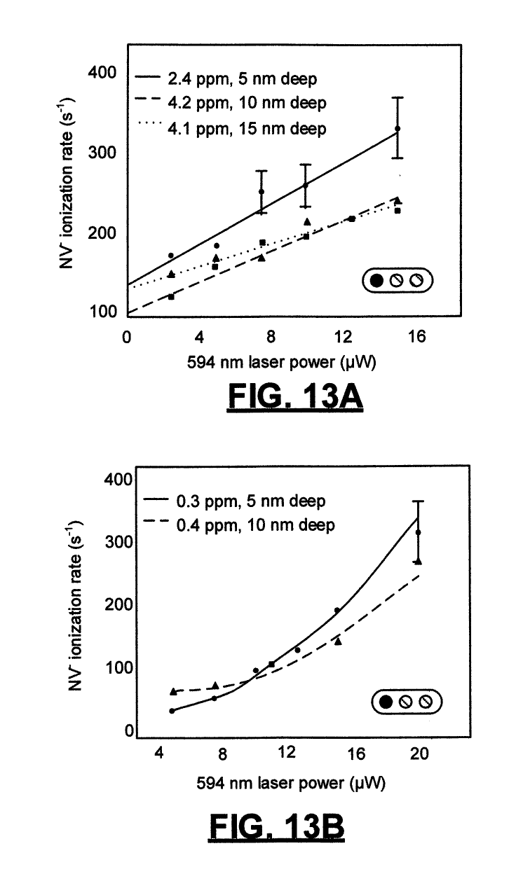

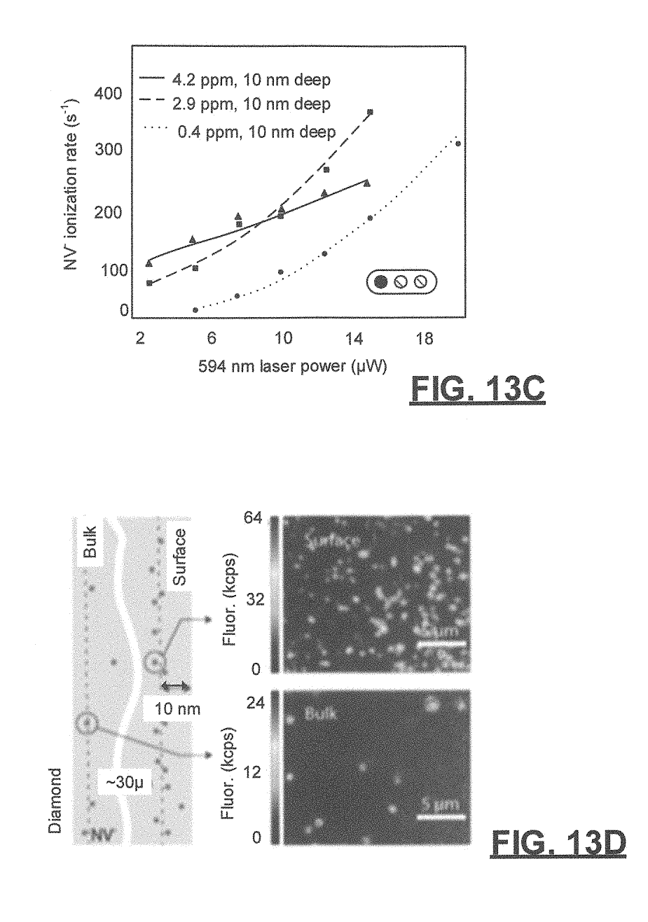

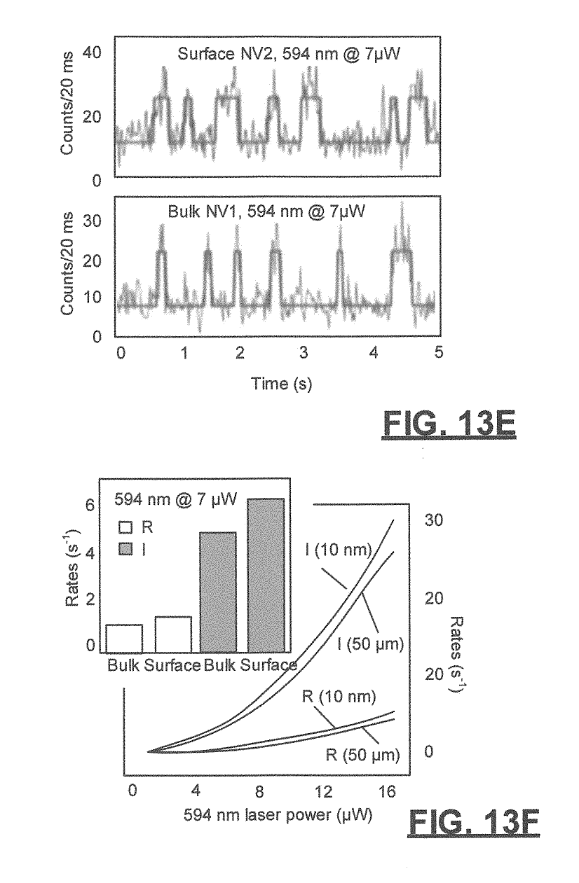

FIG. 13A depicts NV—ionization rates at three different depths for high-density NV ensembles. In all cases, a linear response with laser power (solid lines are linear fits) was observed. FIG. 13B is the same as in FIG. 13A but for the low density end of the implanted strips; ionization rates now grow quadratically (solid lines) with illumination intensity. FIG. 13B depicts NV—ionization rates at three different locations of variable NV⁻ content within the 10-nm-deep implanted strip. FIG. 13D shows confocal fluorescence microscopy in the low density end of the 10-nm-deep strip allows us to identify individual NV⁻ emitters (top image). Displacing the confocal plane to deeper within the bulk crystal, one can probe intrinsic (i.e., not implanted) NVs (lower image), which can then be used as a reference. FIG. 12E shows fluorescence time trace from NVs on the surface (top) and bulk of the crystal (bottom) under cw 594 nm excitation (5 μW); blinking arises from dynamic NV charge ionization and recombination. FIG. 13F shows comparative NV charge recombination (R) and ionization (I) rates for sample surface and bulk NVs (10 nm and 50 μm deep, respectively) as derived from FIG. 13E. The insert shows statistics for a total of 20 NVs at 7 μW. In FIG. 13A through FIG. 13C, ionization rates are determined following the protocol in FIG. 13G, except that a 594 nm laser was used for readout (10 μW and 500 μs, lower right corner); the legend indicates the calculated NV concentration in parts per million (ppm) and depth.

The exact nature of these states in the sample is not fully clear. Recent ab-initio work shows that typical diamond surfaces posses image and acceptor states with sub-bandgap energies that can significantly impact the charge dynamics of shallow color centers such as the NV. As the NV excited triplet hybridize (for example, through mixing with delocalized states), electron scattering away from the defect site upon photo-excitation can lead to single-photon NV⁻ ionization. In the disclosed case surface states, though influential, do not seem to play a dominant role. A first indication is shown in FIG. 13A where the NV—ionization rates were plotted as a function of laser power for different implantation depths. The observed dependence remains linear in all cases although the absolute rates tend to be smaller for deeper NVs. As the NV density decreases, however, the response becomes quadratic, even for the NVs closest to the surface (FIG. 13B). Further, for a given implantation depth, the absolute rates tend to decrease with NV density (FIG. 13C), hence suggesting that state hybridization takes place through mixing with states produced during ion bombardment, for example, those from vacancy complexes forming during typical implantation and annealing protocols.

FIGS. 13D through 13F further support this idea: These figures compare the response from individual NVs either within the bulk of the crystal or near the low-density end of the 10-nm-deep strip (see confocal images in the lower and upper half of FIG. 13D, respectively). To determine the ionization and recombination rates, the fluorescence time trace was recorded during continuous 594 nm excitation, where conversion between the negative and neutral charge states shows in the form of blinking (FIG. 13E). Averaging over a set of individual bulk or shallow NVs (totaling 10 and 12, respectively), similar ionization and recombination rates were found for both groups (FIG. 13F). Crystal imperfections, rather than surface proximity, are believed to be responsible for the observed phenomenology.

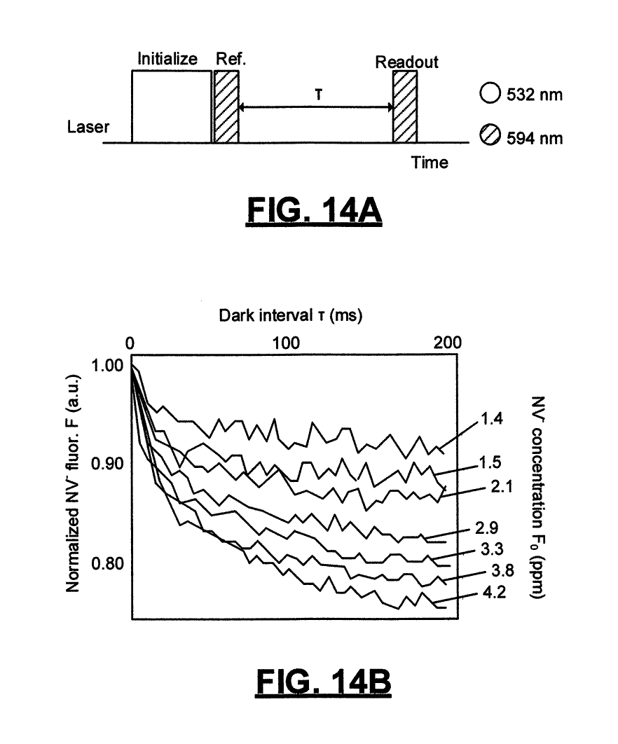

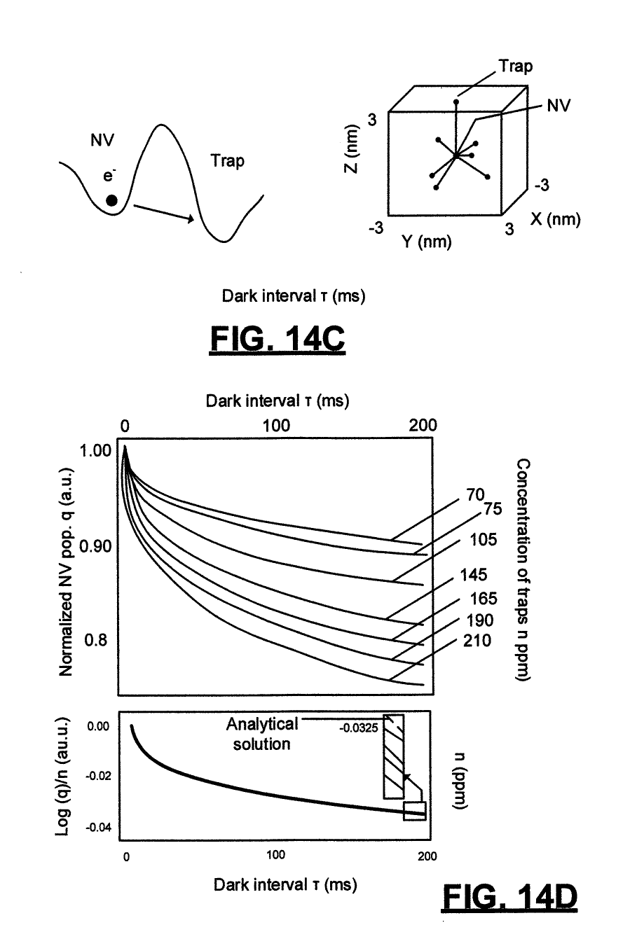

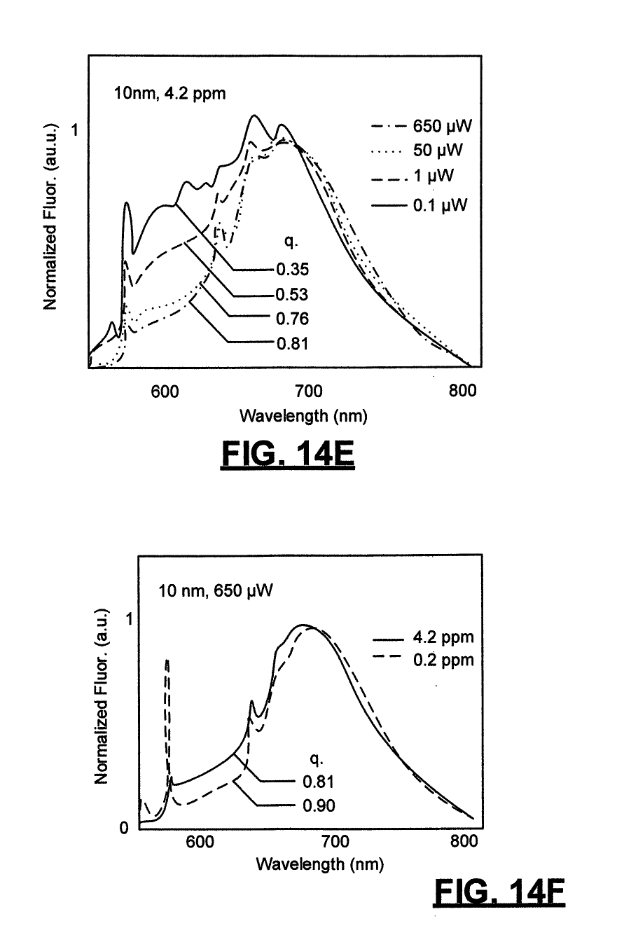

Unlike bulk NVs—where a given charge state remains stable over at least a week (and possibly longer due to ill-defined Fermi levels)—a gradual charge transformation in the dark was found, preferentially to the neutral state. FIG. 14A to 14F contains a summary of these observations: Following charge initialization via a 50 μW, 532 nm laser pulse, the system evolution was probed by comparing the NV⁻ fluorescence determined from 594 nm readout pulses immediately after the green pulse and following a dark time interval T (FIG. 14A). The upper half of FIG. 14B contains the results for various NV densities along the 10 nm deep implantation strip. In all cases the NV⁻ population progressively decays with time at a gradually diminishing rate. A clear correlation was found between the local nitrogen implantation density and the fraction of negatively charged NVs transforming to neutral at a given time. Because the former arguably correlates with the local number of defects in the diamond lattice, these observations indicate that charge capture by trap states—a process distinctly different from band-bending—is responsible for the gradual discharge of NV− in the dark. These results were qualitatively reproduced via a kinetic Monte Carlo where the excess electron of a negatively charged NV at the center of a virtual diamond lattice randomly transfers to a neighboring trap (FIG. 14C). In this model t the unit time probability characterizing the electron transfer was assumed to decrease exponentially with the distance between the NV and the trap. The upper half in FIG. 14D shows the averaged results of simulations for different trap densities, which are assumed to be proportional to the local nitrogen concentration. Reasonable agreement with the experimental observations (FIG. 14B) was obtained, namely the calculated time dependence has the same overall shape featuring a fast decay followed by an increasingly slow evolution; as expected, the fraction of NV⁻ transforming into NV⁰ grows with the trap density.

FIG. 14A depicts schematics of the experimental protocol. After initialization into NV⁻ via 532 nm laser pulse (50 μW, 10 ms), the fractional NV⁻ population was determined by comparing the fluorescence from a reference pulse to that of readout pulse following a dark interval of variable duration τ; the wavelength, power, and duration of both the reference and readout pulses are 594 nm, 10 μW and 500 μs, respectively. FIG. 14B (Top) NV⁻ fluorescence F in the dark as a function of τ for various 10-nm-deep NV⁻ densities expressed in terms of F₀, the fluorescence at τ=0. (Bottom) Renormalized fluorescence, see FIG. 14C (Left). In the presence of neighboring traps, negatively charged NVs can transform into neutral via electron tunneling or thermal activation. In FIG. 14C (Right) shows a reproduction of the observed dynamics. A kinetic Monte Carlo model comprising an NV center and a random distribution of charge traps over a (5 nm)³ virtual crystal lattice was used. FIG. 14D (Top) Averaged time response of the fractional NV⁻ population for a variable number of traps N as calculated from kinetic Monte Carlo. (Bottom) Renormalized fractional NV⁻ population. Also shown for comparison is the analytical solution assuming the charge trap probability distribution is continuous over space. FIG. 14E depicts optical spectroscopy of 10-nm-deep NVs under 532 nm excitation for various laser intensities in the high-density region of the implantation strip. FIG. 14F is the same as above but for fixed laser power (650 μW) and two different NV concentrations.

To gain a better understanding of the processes at play the NV⁻ fraction q_(t) at a given time t was written as

q_(t)∝ [symbol] exp((−Σᵢ^{t}/τᵢⱼ)) [symbol] ⱼ, (1)

where 1/τᵢⱼ∝exp(−krᵢⱼ) is the unit time probability of a charge transfer from the j-th NV⁻ to the ⁱ-th trap at a distance rᵢⱼ, k is a constant, and brackets indicate average over all negatively-charged NVs. Assuming that traps are uniformly distributed with density n and that NVs are sufficiently sparse (so that a given trap cannot be accessed by electrons from different NVs), Eq. (1) takes the form

q_(t)∝exp((n/n_{eff}g(t/τ_{eff})) (2)

where (t/τ_{eff}) is a function of time, and n_{eff} and 1/τ_{eff} are defect-specific constants. Provided one takes logarithm and divides the result in each case by the corresponding trap density n, it follows from Eq. (2) that all traces must collapse into a single ‘universal’ response. As shown in the lower half of FIGS. 14B and 14D, the experimental and numerical results are consistent with this prediction. Reasonable agreement with an analytical formula derived from assuming a continuous (i.e., non-discrete) distribution of traps (dashed black trace in the lower half of FIG. 14D) was also found, though the predicted NV⁻ population takes slightly higher values at longer times (see figure inset).

Since 532 nm illumination induces NV charge interconversion between negative and neutral, the fractional NV⁻ content under continuous optical excitation emerges from the interplay between the ionization and recombination rates as well as the NV⁻ charge transfer rate to neighboring traps. This is demonstrated in FIG. 14E where the optical spectra are collected from the high-density end of the NV strips for 532 nm illumination of variable intensity. For all implantation depths the NV fraction invariably grows with laser power, starting from a minimum of about 35% for 0.1 μW to about 81% for about 600 μW.

The exact NV⁻ content is difficult to extract with accuracy because the NV⁻ contribution to the spectrum has a different shape relative to that observed in individual bulk NVs. The Stokes-shifted section of the spectrum has a greater relative size, which was interpreted as an indication of additional phonon-mediated optical relaxation channels. Similar to the trend in FIG. 13C, the NV⁻ fraction converges to bulk crystal values as the concentration of shallow NVs becomes lower (FIG. 14F).

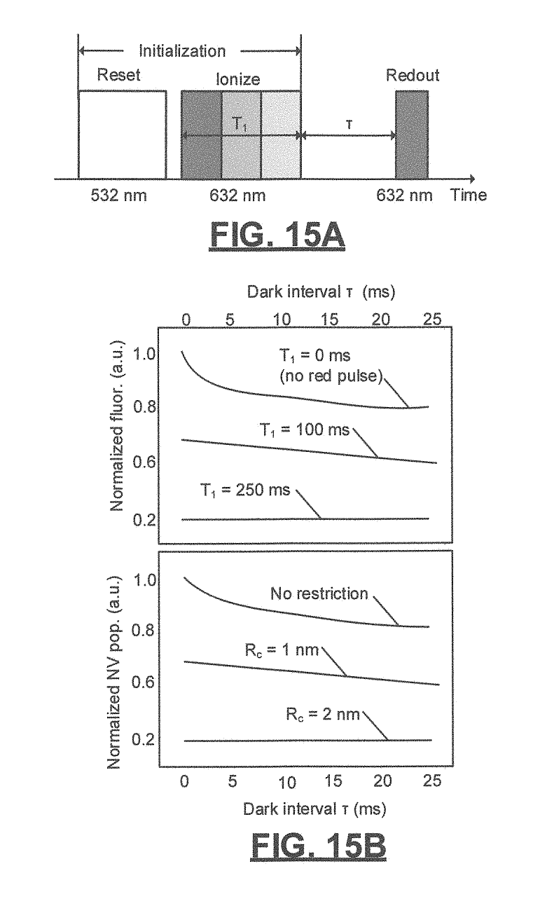

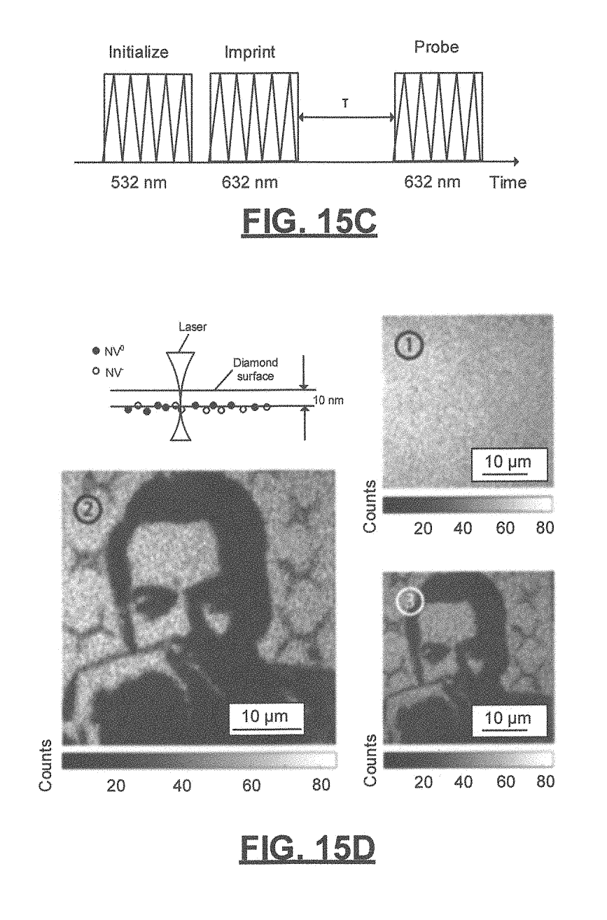

Interestingly, the NV⁻ charge dynamics in the dark was found to depend on the illumination history. FIG. 15A introduces an example protocol where 532 nm initialization is followed by partial 632 nm bleach. Compared to the case where no red pulse is applied (upper light blue trace), a modified, slower charge conversion (middle dark blue trace) was found, which may be rationalized in terms of an altered microscopic charge environment. More specifically, since the faster changing segment in the q_(t) curve can be related to the shorter charge transfer times (see Eq. (1)), this observation can be qualitatively reproduced by imposing a critical radius R_{c} below which no traps are available (see simulated traces in the lower half of FIG. 15B). Physically, the latter amounts to assuming that red illumination preferentially transfers the excess NV⁻ electron to the nearest empty trap—perhaps via photo-induced tunneling from the excited state. The NV⁻ fluorescence slightly tends to grow after a near full bleach (green trace in the upper half of FIG. 15B), thus hinting at a non-negligible NV⁻ equilibrium population in the dark.

FIGS. 15A to 15C depict an experimental protocol. Following 532 nm initialization (17 μW, 15 ms) and partial NV⁻ ionization via 632 nm illumination of variable duration (17 μW), the fractional NV⁻ population was probed via a 632 nm readout pulse (17 μW, 500 μs) after a dark time interval T. FIG. 15B (Top) shows measured NV—fluorescence as a function of T for red ionization of different intensities, as shown in the figure labels; solid lines are guides to the eye. FIG. 154B (Bottom) shows calculated response as determined from a kinetic Montecarlo simulation assuming a trap density of 210 ppm. The upper, light blue trace reproduces the calculation in FIG. 13D for the corresponding time window; the lower traces use the exact same model except that one assumes no traps are available within a sphere of critical radius R_{c} (1 and 2 nm for the middle and lower traces, respectively). In each case, the initial charge state of the NV is chosen to match the measured NV⁻ fractional population at zero delay. FIG. 4C shows a charge imprinting protocol; zig-zags indicate laser scan. FIG. 4D illustrates proof-of-principle data encoding in the high-density (420 ppm N concentration) segment of the on 10-nm-deep implantation strip. Following initialization via five 532 nm scans (image 1 in the upper right) shallow NV⁻ were selectively ionized to create a pre-defined charge pattern (lower left). Images 2 and 3 show the result via a 632 nm readout scan after a wait time T of one minute and 15 hours, respectively. The 532 nm laser power and illumination time per pixel is 17 μW and 2 ms, respectively; the power and illumination time during 632 nm NV⁻ ionization is 17 μW and 0-20 ms, respectively. In all cases, readout is carried out via a 632 nm scan (17 μW, 2 ms integration time per pixel).

The physical nature of the charge traps at play is presently unclear but vacancy complexes play a dominant role. Among the latter, the di-vacancy V₂—a defect forming efficiently via diffusion of single vacancies during typical sample annealing protocols—lists as the most likely candidate. Ab initio calculations indicate the ground state of both the neutral and negatively charged V₂ lie below that of NV⁻, hence making electron transfer to these defects energetically favorable. Another relevant defect is the Nₛ-V-Nₛ complex, also forming during annealing in nitrogen-rich diamond and potentially able to adopt a negatively charged state via electron capture from NV⁻. While neutral vacancies could also serve as electron traps, its characteristic zerophonon-line at 741 nm is absent in the optical spectra from this sample (see below) and can, therefore, be ruled out.

The disclosed technology can be used for the long-term charge conversion dynamics of NVs, a subject relevant to applications in electric field sensing (where multisecond-long processes are not uncommon), and for data storage (where charge stability over several days or more is a requisite). The latter use is particularly intriguing because sub-diffraction charge control—e.g., with the aid of near-field scanning microscopy 30—could be exploited to create ultra-dense optical memories. As a first step in this direction, the protocol of FIG. 15C may be implemented: Upon initializing NVs in the negatively charged state over a large area (about 40×40 μm² in the high-density end of the 10-nm-deep implantation strip), NV⁻ into NV⁰ was selectively photoionized via 632 nm light so as to encode an arbitrary charge pattern (in this case, the well-known portrait of Richard Feynman). The result was probe via a quick 632 nm laser scan following a variable dark time interval T. FIG. 15D displays images of the area of interest after charge initialization and encoding. Using as a reference the result obtained minutes after encoding (image 2 in FIG. 15D), preferential transformation into NV⁰ within the NV⁻-rich areas was observed; dark regions of the pattern, on the other hand, exhibit non-negligible back-conversion into NV⁻. Despite these ongoing processes, good contrast was obtained even for dark intervals exceeding 15 hours (image 3 in FIG. 15D).

In summary, the experiments show that shallow NVs exhibit singular charge dynamics in the form of single photon ionization and recombination, and charge interconversion in the dark. The impact of these processes on the system response correlates with the nitrogen content, stronger in areas of higher ion implantation density. Since the charge dynamics of isolated shallow and bulk NVs is similar, the phenomena observed in ensembles arise from the presence of other defects created during ion implantation and sample annealing, possibly substitutional nitrogen and di-vacancies. In the limit of high defect concentrations, one can rationalize single-photon NV⁻ ionization as a manifestation of inter defect proximity effects, e.g., in the form of hybridization of the NV⁻ excited states with trap states. Depending on the target application, state mixing with neighboring traps could be exploited, for instance, to enhance the selectivity of spin-to-charge conversion protocols, relevant to nanoscale sensing.

Optimized NV engineering protocols may be used—including delta-doping, and annealing at higher temperatures or upon overgrowth of a boron-doped layer—may help stabilize the charge state of shallow NVs over longer time windows, of interest for data storage. Alternatively, surface termination could be tailored to make NV charge conversion sensitive to electrochemical processes on the diamond surface. By the same token, experiments as a function of temperature will be useful to separately assess the contribution of tunneling and thermal activation to the electron transfer affecting NV⁻ in the dark.

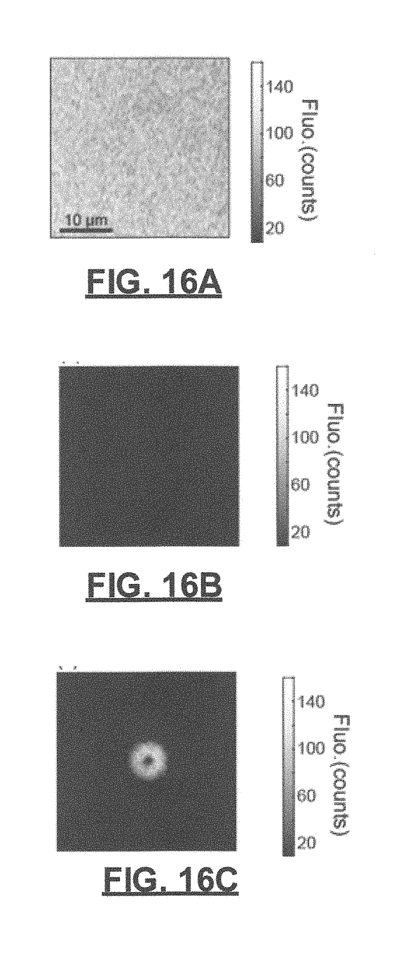

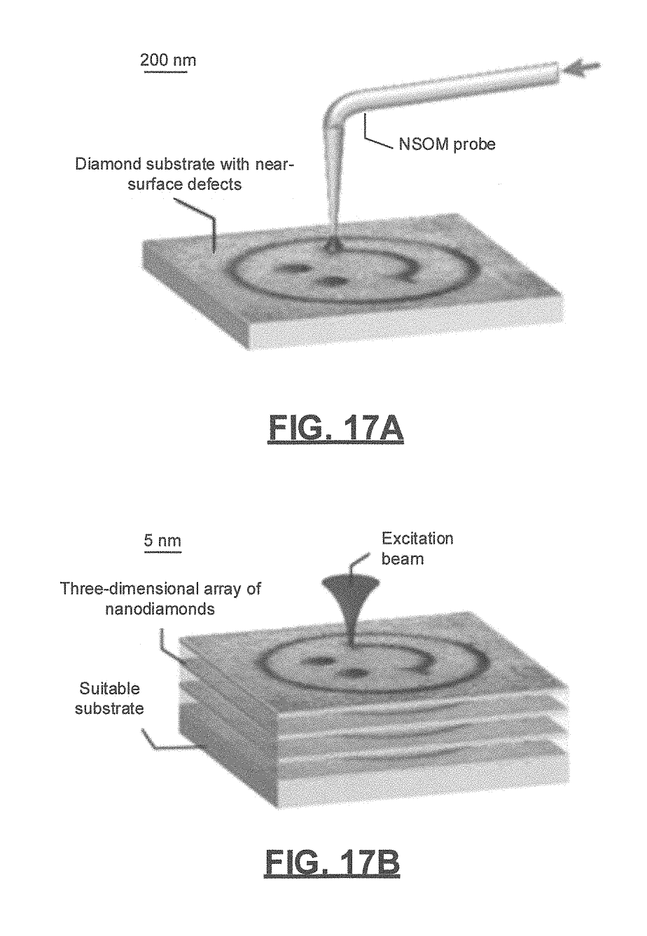

In one embodiment, the system is used for storing information by utilizing charge-state control of silicon-vacancy centers in diamond: Results similar to those shown in FIG. 1A and FIG. 1B can be obtained by employing analogous experimental protocols that allow charge-state control of SiV centers in diamond. (a figure demonstrating SiV—ring formation upon red park can be added in FIG. 1A and FIG. 1B, as an example). FIG. 16A; FIG. 16B and FIG. 16C depict fluorescence images of a diamond plane initialized in (FIG. 16A) SiV⁻ state, (FIG. 16B) SiV⁰ state, (FIG. 16C) patterned SiV⁻ and SiV⁰ states.

In another embodiment, the disclosed system can be used to control charge-state of superficial defects using near-field scanning optical microscopy (NSOM) for ultra-dense two-dimensional memory storage: Near-field scanning optical microscopy enables sub-diffraction imaging of fluorescent centers by means of a probe that delivers laser power to a tightly confined spot with nanometric precision. This technique also offers a way to optically control the charge-state of individual near-surface defects and thus can be used for ultra-dense two-dimensional memory storage (see FIG. 17A). In another embodiment, the disclosed system can be used to control charge-state of superficial defects using near-field scanning optical microscopy (NSOM) for ultra-dense two-dimensional memory storage: Near-field scanning optical microscopy enables sub-diffraction imaging of fluorescent centers by means of a probe that delivers laser power to a tightly confined spot with nanometric precision. This technique also offers a way to optically control the charge-state of individual near-surface defects and thus can be used for ultra-dense two-dimensional memory storage.

In another embodiment, the disclosed system can be used as a three-dimensional memory storage system using artificial lattice of nanodiamonds. Using similar experimental protocols, optically active defects in nanodiamonds can be used for storing classical information. Thin-films of nanodiamonds can be obtained via spin-coating/drop-casting nanodiamonds on a suitable substrate. Moreover, a three-dimensional artificial lattice formed by stacking multiple layers of these nanodiamond-thin-films, sandwiched between layers of transparent organic material such as Poly-methyl-methacrylate (PMMA), provides a robust platform for memory storage in three-dimensions (see FIG. 17B). The advantage of such a device is that there will be negligible crosstalk between neighboring nanodiamonds, making individual nanodiamonds the true classical-bits of information. Also, a variety of substrates ranging from flexible substrates to metallic substrates can be employed as per the application requirements. The use of nanodiamonds also makes this approach financially more viable and easier to mass produce.

In yet another embodiment, the disclosed system can be used as ultra-dense three-dimensional memory storage using combination of optical charge-state control of defects and stimulate emission depletion microscopy (STED) techniques: Stimulated emission depletion (STED) microscopy is one of the far-field techniques that allows imaging of fluorescent centers with sub-diffraction resolution by utilizing a Gaussian excitation beam overlaid with a donut STED beam. If a defect with optically controllable charge-state can also undergo stimulated emission without changing its charge state, then all-optical super-resolution ‘read’ and ‘write’ protocols can address target defects without altering affecting the charge state of neighboring defects within the illuminated (diffraction-limited) spot. This means that STED protocols can then be used for ultra-dense three-dimensional information storage, without any need of additional temporary memory (such as 14N nuclear spin, in the case of an NV center). Currently, no defects are known that can exhibit both of these properties simultaneously, but the odds of finding one in either an inorganic or an organic system are definitely non-zero.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A method for storing and retrieving information in a substrate, the method comprising steps of:
irradiating spin-defect centers in a substrate with a first wavelength of light, the step of irradiating causing a plurality of the spin-defect centers to change from a first charge state to a second charge state, wherein the plurality of spin-defect centers with the second charge state centers are selected to form a first pattern that corresponds to predetermined information to be stored; and
optically detecting the first pattern of spin-defect centers with the second charge state to thereby retrieve the predetermined information.

2. The method as recited in claim 1, wherein the spin-defect centers are nitrogen-vacancy centers and the substrate is a diamond substrate.

3. The method as recited in claim 1, wherein the spin-defect centers are silicon-vacancy centers and the substrate is a diamond substrate.

4. The method as recited in claim 1, wherein the spin-defect centers are silicon vacancy centers and the substrate is a silicon carbide substrate.

5. The method as recited in claim 1, wherein the spin-defect centers are silicon-carbon di-vacancies and the substrate is a silicon carbide substrate.

6. The method as recited in claim 1, wherein the spin-defect centers are rare earth ions and the substrate is a garnet.

7. The method as recited in claim 1, wherein the spin-defect centers are cerium ions and the substrate is a yttrium aluminum garnet (YAG).

8. The method as recited in claim 1, wherein the spin-defect centers are irradiated using near-field scanning optical microscope (NSOM) to achieve sub-diffraction resolution in two-dimensions.

9. A method for storing information in a diamond substrate, the method comprising a step of:
irradiating negatively charged nitrogen-vacancy (NV⁻) centers in a diamond substrate with a first wavelength of light, the first wavelength of light being selected from a red wavelength between 580 nm and 636 nm or a blue wavelength of light between 430 nm and 470 nm, the step of irradiating causing a plurality of negatively charged nitrogen-vacancy (NV⁻) centers to be altered by changing the plurality of negatively charged nitrogen-vacancy (NV⁻) centers to neutral NV⁰ centers, wherein the plurality of negatively charged nitrogen-vacancy (NV⁻) centers are selected to form a first pattern of neutral NV⁰ centers, the first pattern corresponds to predetermined information to be stored.

10. The method as recited in claim 9, further comprising a step of optically detecting the first pattern of neutral NV⁰ centers to thereby retrieve the predetermined information.

11. The method as recited in claim 10, wherein the step of optically detecting the first pattern comprises irradiating the first pattern of neutral NV⁰ centers with red light to produce a corresponding fluorescence and collecting the corresponding fluorescence.

12. The method as recited in claim 9, further comprising a step of initializing the plurality of negatively charged nitrogen-vacancy (NV⁻) centers by irradiating with a predetermined wavelength of light to convert a plurality of nitrogen-vacancy (NV) centers in the diamond substrate to the plurality of negatively charged nitrogen-vacancy (NV⁻) centers, the step of initializing being performed prior to the step of irradiating.

13. The method as recited in claim 12, wherein the predetermined wavelength of light is a green wavelength.

14. The method as recited in claim 9, wherein the first wavelength of light is the blue wavelength of light between 430 nm and 470 nm.

15. The method as recited in claim 9, further comprising a step of erasing the first pattern of neutral NV⁰ centers by irradiating with a green wavelength of light to change the neutral NV⁰ centers to NV⁻ centers, the green wavelength of light having a wavelength between 510 nm and 560 nm.

16. The method as recited in claim 9, wherein diamond substrate has a surface and the plurality of NV⁻ centers include:
a first plurality of negatively charged (NV⁻) centers disposed in a first plane at a first depth below the surface; and
a second plurality of negatively charged (NV⁻) centers disposed in a second plane at a second depth below the surface, wherein the first depth and the second depth are different;
wherein the step of irradiating selectively irradiates the first plurality of negatively charged (NV⁻) centers but not the second plurality of negatively charged (NV⁻) centers, thus storing information in three-dimensions.

17. The method as recited in claim 9, wherein the diamond substrate comprises a layer of nanodiamond sandwiched between adjacent layers of a transparent organic polymer.

18. The method as recited in claim 9, wherein diamond substrate is stored in a dark environment for at least one week and the first pattern remains unchanged over the at least one week.

19. A method for storing information in a substrate with sub-diffraction resolution, the method comprising sequential steps of:
selecting a target spin-defect center from a plurality of spin-defect centers which are disposed in a substrate, wherein the target-spin-defect centers is proximate peripheral spin-defect centers, the plurality of spin-defect centers forming a first pattern;
irradiating the plurality of spin-defects centers, including the target spin-defect center, with a first wavelength of light, the step of irradiating changing a charge state of the target spin-defect center without altering nuclear spin states of either the target spin-defect center or the peripheral spin-defect centers, the step of irradiating causing the first pattern to change into a second pattern that corresponds to predetermined information;
irradiating each peripheral spin-defect center, but not the target spin-defect center, with light to restore each peripheral spin-defect center's charge state based on each peripheral spin-defect center's nuclear spin state.

20. The method as recited in claim 19, wherein the plurality of spin-defect centers are nitrogen-vacancy (NV) centers and the substrate is a diamond substrate.
